(19) United States
(12) Patent Application Publication
(10) Pub. No.: US 2024/0395862 A1
(43) Pub. Date: Nov. 28, 2024

(54) SEMICONDUCTOR DEVICES

(71) Applicant: SAMSUNG ELECTRONICS CO., LTD., Suwon-si (KR)

(72) Inventors: Sungmin KIM, Suwon-si (KR); Yeonsook KIM, Suwon-si (KR); Yoon-Hee LEE, Suwon-si (KR); Yechan KIM, Suwon-si (KR)

(21) Appl. No.: 18/509,925

(22) Filed: Nov. 15, 2023

(30) Foreign Application Priority Data
May 25, 2023 (KR) 10-2023-0067597

(51) Int. Cl. H01L 29/06; H01L 23/48; H01L 27/092; H01L 29/417; H01L 29/423; H01L 29/775; H01L 29/786

(52) U.S. Cl. CPC H01L 29/0673; H01L 23/481; H01L 27/092; H01L 29/41733; H01L 29/42392; H01L 29/775; H01L 29/78696

(57) ABSTRACT

Provided is a semiconductor device comprising: a semiconductor substrate; source/drain patterns spaced apart in a first direction on the semiconductor substrate; and channel patterns on the semiconductor substrate, wherein at least one of the channel patterns is between adjacent source/drain patterns among the source/drain patterns, wherein at least one of the channel patterns includes a plurality of semiconductor patterns, and the plurality of semiconductor patterns are spaced apart from each other in a second direction that is perpendicular to an upper surface of the semiconductor substrate, wherein the semiconductor substrate includes a {110} crystal plane, wherein at least one of the channel patterns includes a surface pattern, wherein the surface pattern includes first surfaces and second surfaces, wherein the first surfaces include protruding edges, wherein the second surfaces are respectively connected to the first surfaces through protruding edges, and wherein the protruding edges are arranged in a third direction.

### CROSS-REFERENCE TO RELATED APPLICATIONS

This U.S. non-provisional patent application claims priority under 35 U.S.C. § 119 to Korean Patent Application No. 10-2023-0067597, filed on May 25, 2023, in the Korean Intellectual Property Office, the entire contents of which are hereby incorporated by reference.

### BACKGROUND OF THE INVENTION

The present disclosure relates to semiconductor devices.

Semiconductor devices may include an integrated circuit including metal oxide semiconductor field effect transistors (MOSFETs). As the size of semiconductor devices and design rules are gradually reduced, the scale down of MOSFETs is also accelerating. The size reduction of the MOSFETs may cause a short channel effect, which may deteriorate operating characteristics of the semiconductor devices. Accordingly, various methods for forming semiconductor devices having superior performance while overcoming the limitations of high integration of the semiconductor devices are being studied.

### SUMMARY

The present disclosure may provide semiconductor devices with improved electrical characteristics and reliability.

The present disclosure may provide methods of manufacturing semiconductor devices with improved electrical characteristics and reliability.

A semiconductor device according to some embodiments of the present disclosure may include a semiconductor substrate; source/drain patterns spaced apart in a first direction on the semiconductor substrate; and channel patterns on the semiconductor substrate, wherein at least one of the channel patterns is between adjacent source/drain patterns among the source/drain patterns, wherein at least one of the channel patterns includes a plurality of semiconductor patterns, and the plurality of semiconductor patterns are spaced apart from each other in a second direction that is perpendicular to an upper surface of the semiconductor substrate, wherein the semiconductor substrate includes a {110} crystal plane, wherein at least one of the channel patterns includes a surface pattern, wherein the surface pattern includes first surfaces and second surfaces, wherein the first surfaces include protruding edges, wherein the second surfaces are respectively connected to the first surfaces through protruding edges, and wherein the protruding edges are arranged in a third direction.

A semiconductor device according to some embodiments of the present disclosure may include a semiconductor substrate; an epitaxial layer on the semiconductor substrate; source/drain patterns spaced apart in a first direction on the epitaxial layer; channel patterns on the epitaxial layer, wherein at least one of the channel patterns is between adjacent source/drain patterns among the source/drain patterns; a gate electrode on at least one of the channel patterns; a gate insulating layer between the gate electrode and the channel patterns; an interlayer insulating layer on the gate insulating layer; and active contacts electrically connected to the source/drain patterns through the interlayer insulating layer, wherein the semiconductor substrate includes a first surface that comprises a {110} crystal plane, wherein the epitaxial layer includes a second surface that comprises a {110} crystal plane, and wherein an upper surface of the semiconductor substrate is inclined from the first surface by a crystal off angle.

A semiconductor device according to some embodiments of the present disclosure may include an epitaxial layer; source/drain patterns spaced apart in a first direction on the epitaxial layer; and channel patterns on the epitaxial layer, wherein at least one of the channel patterns is between adjacent source/drain patterns among the source/drain patterns; a gate electrode on at least one of the channel patterns; a gate insulating layer between the gate electrode and the channel patterns; an interlayer insulating layer on the gate insulating layer; and active contacts electrically connected to the source/drain patterns through the interlayer insulating layer; a lower power wiring on a lower surface of the epitaxial layer; and a back contact electrically connecting the lower power wiring and the source/drain patterns through the epitaxial layer, wherein the epitaxial layer comprises a {110} crystal plane, wherein the epitaxial layer includes a first surface pattern that includes first edges protruding in a second direction perpendicular to the first direction, wherein the first surface pattern includes first surfaces and second surfaces that are respectively connected to the first surfaces through the first edges, wherein at least one of the channel patterns includes a second surface pattern that includes second edges protruding in the second direction, and wherein the second surface pattern includes third surfaces and fourth surfaces that are respectively connected to the third surfaces through the second edges.

### BRIEF DESCRIPTION OF THE DRAWINGS

The embodiments of the present disclosure will be more clearly understood from the following brief description taken in conjunction with the accompanying drawings. The accompanying drawings represent non-limiting, example embodiments of the present disclosure as described herein.

FIG. 1 is a plan view illustrating a semiconductor device according to some embodiments of the present disclosure.

FIGS. 2A, 2B, 2C, and 2D are cross-sectional views taken along lines A-A′, B-B′, C-C′, and D-D′ of FIG. 1, respectively.

FIG. 3 is an enlarged view of a portion ‘CU1’ of FIG. 2D.

FIG. 4A is an enlarged view of first, second, and third semiconductor patterns SP1, SP2, and SP3 included in a first channel pattern CH1 and a second channel pattern CH2.

FIG. 4B is a plan view illustrating a first channel pattern CH1 for explaining some embodiments of the present disclosure.

FIGS. 5 to 14C are views illustrating a method of manufacturing a semiconductor device according to some embodiments of the present disclosure.

FIGS. 15A and 15B are views of a semiconductor device according to some embodiments of the present disclosure, which are cross-sectional views taken along lines A-A′ and B-B′ of FIG. 1, respectively.

### DETAILED DESCRIPTION

Hereinafter, the present disclosure will be described in detail by describing embodiments of the present disclosure with reference to the accompanying drawings.

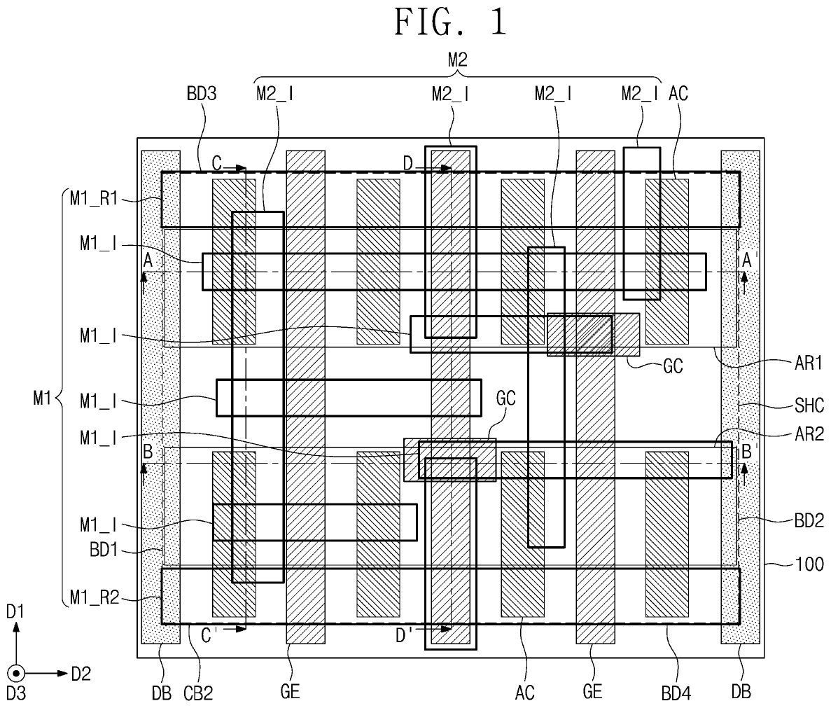

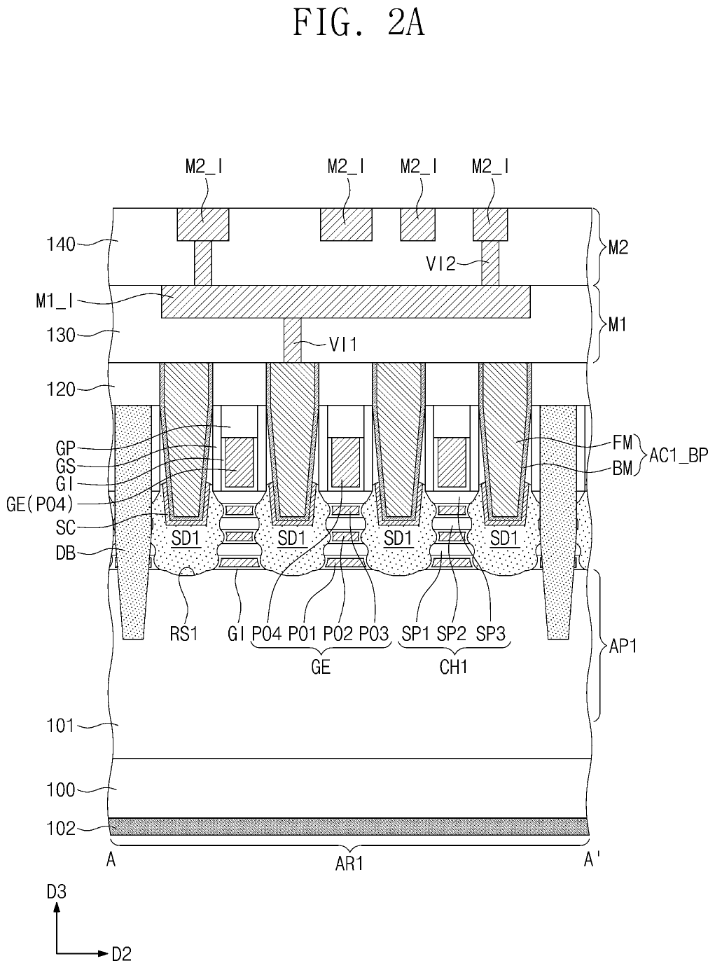

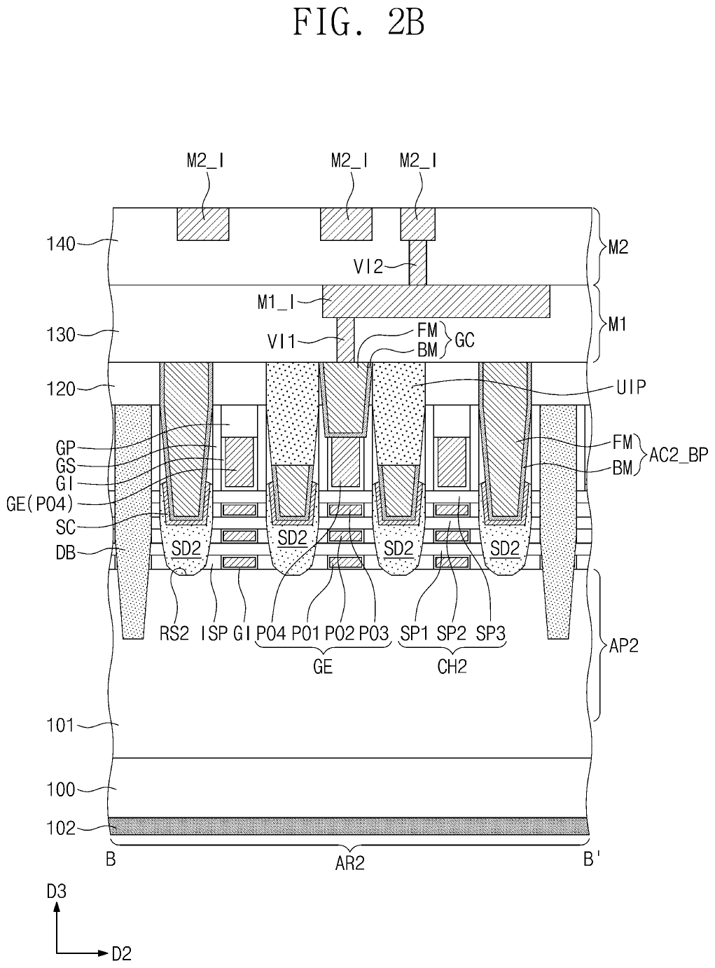

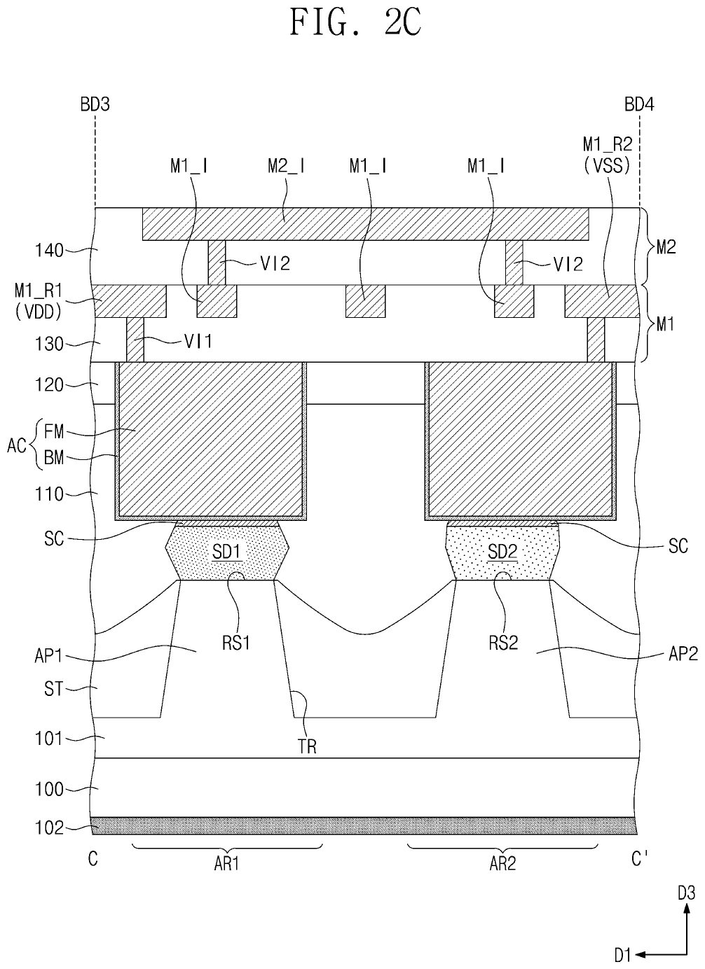

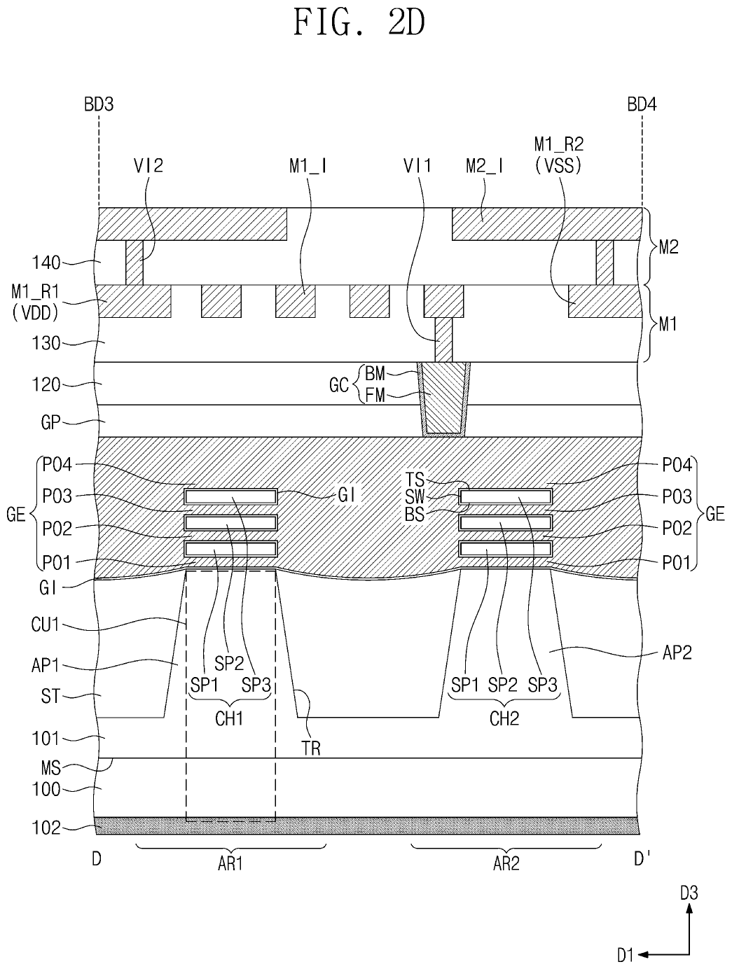

FIG. 1 is a plan view illustrating a semiconductor device according to some embodiments of the present disclosure. FIGS. 2A, 2B, 2C, and 2D are cross-sectional views taken along lines A-A′, B-B′, C-C′, and D-D′ of FIG. 1, respectively.

Referring to FIGS. 1 and 2A, 2B, 2C, and 2D, a substrate 100 may be a semiconductor substrate including, for example, silicon, germanium, silicon-germanium, or the like, or a compound semiconductor substrate. For example, the substrate 100 may be a silicon single crystal substrate.

The substrate 100 may have a {110} crystal plane. The substrate 100 may include a first active region AR1 and a second active region AR2. Each of the first and second active regions AR1 and AR2 may extend in the second direction D2. The first active region AR1 may be one of an n-type metal oxide semiconductor field effect transistor (NMOSFET) region and a p-type metal oxide semiconductor field effect transistor (PMOSFET) region, and the second active region AR2 may be the other one of an NMOSFET region and a PMOSFET region. As an example, the first active region AR1 may be an NMOSFET region, and the second active region AR2 may be a PMOSFET region.

The substrate 100 may include an impurity of a first conductivity type (e.g., p-type) and an impurity of a second conductivity type (e.g., n-type). The impurities of the first and second conductivity types may be included in the PMOSFET region and the NMOSFET region, respectively. The impurity of the first conductivity type may include, for example, boron, gallium, and/or indium. The impurity of the second conductivity type may include, for example, nitrogen, phosphorus, arsenic, and/or antimony. A concentration of each of the impurity of the first conductivity type and the impurity of the second conductivity type in the substrate 100 may correspond to 1.00E⁺¹⁸/cm³ to 1.00E⁺²⁰/cm³. Although not shown, the substrate 100 may include a notch NC in a <100> direction. The <100> direction may be referred to as a first direction D1 in this specification. A <110> direction to be described later may be referred to as a second direction D2 in this specification and may be perpendicular to the first direction D1. A third direction D3 may be a direction perpendicular to a lower surface of the substrate 100. The direction D1 to D3 directions can be defined in a semiconductor substrate that comprises {110} crystal plane.

A diffusion barrier layer 102 may be disposed on the lower surface of the substrate 100. The diffusion barrier layer 102 may be disposed apart from an epitaxial layer 101 to be described later in the third direction D3. A thickness of the diffusion barrier layer 102 in the third direction D3 may be 40 angstroms (Å) or more. The diffusion barrier layer 102 may include, for example, silicon oxide and/or silicon nitride. As the diffusion barrier layer 102 is disposed on the lower surface of the substrate 100, the impurities in/on the substrate 100 may be prevented from diffusing to the outside. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

An epitaxial layer 101 may be disposed on the substrate 100. The epitaxial layer 101 may be a semiconductor layer including, for example, silicon, germanium, silicon-germanium, or the like, or a compound semiconductor layer. For example, the epitaxial layer 101 may be a silicon single crystal substrate.

The epitaxial layer 101 may have the same crystal plane as the substrate 100. The epitaxial layer may have a thickness of 0.5 micrometers (μm) to 10 μm. The epitaxial layer 101 may have a {110} crystal plane.

The epitaxial layer 101 may include the first active region AR1 and the second active region AR2. Each of the first and second active regions AR1 and AR2 may extend in the second direction D2. The first active region AR1 may be one of an NMOSFET region and a PMOSFET region, and the second active region AR2 may be the other one of an NMOSFET region and a PMOSFET region. As an example, the first active region AR1 may be an NMOSFET region, and the second active region AR2 may be a PMOSFET region.

A first active pattern AP1 and a second active pattern AP2 may be defined by a trench TR formed on/in the epitaxial layer 101. The first active pattern AP1 may be provided on/in the first active region AR1, and the second active pattern AP2 may be provided on/in the second active region AR2. The first and second active patterns AP1 and AP2 may extend in the second direction D2. The first and second active patterns AP1 and AP2 may be portions of the substrate 100 (and/or portions of the epitaxial layer 101) and may be vertically protruding portions.

The epitaxial layer 101 may include an impurity of a first conductivity type (e.g., p-type) and an impurity of a second conductivity type (e.g., n-type). The impurity of the first conductivity type may be included in the PMOSFET region, and the impurity of the second conductivity type may be included in the NMOSFET region. The impurity of the first conductivity type may include, for example, boron, gallium, and/or indium. The impurity of the second conductivity type may include, for example, nitrogen, phosphorus, arsenic, and/or antimony. A concentration of impurities included in the epitaxial layer 101 may be lower than a concentration of impurities included in the substrate 100. In detail, the concentration of each of the first conductivity type impurity and the second conductivity type impurity in the epitaxial layer 101 may be 1.00E⁺¹⁴/cm³ to 5.00E⁺¹⁷/cm³. Although not shown, the epitaxial layer 101 may include a transient layer 103. For example, the transient layer 103 may be on an upper surface of the substrate 100. The transient layer 103 may include an impurity diffused from the substrate 100 into the epitaxial layer 101.

A device isolation layer ST may be provided on/in the epitaxial layer 101. The device isolation layer ST may at least partially fill the trench TR. The device isolation layer ST may include, for example, a silicon oxide layer. The device isolation layer ST may not cover first and second channel patterns CH1 and CH2 to be described later. For example, the device isolation layer ST may not overlap with the first and second channel patterns CH1 and CH2 in the third direction D3. As used herein, “an element A overlapping an element B in a direction X” (or similar language) means that there is at least one line that extends in the direction X and intersects both the elements A and B.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3 sequentially stacked. The first, second, and third semiconductor patterns SP1, SP2, and SP3 may be spaced apart from each other in a vertical direction (e.g., in the third direction D3).

Each of the first, second, and third semiconductor patterns SP1, SP2, and SP3 may include, for example, silicon (Si), germanium (Ge), and/or silicon-germanium (SiGe). For example, each of the first, second, and third semiconductor patterns SP1, SP2, and SP3 may include crystalline silicon.

A plurality of first source/drain patterns SD1 may be provided on the first active pattern AP1. The first source/drain patterns SD1 may be spaced apart from each other in the second direction D2. A plurality of first recesses RS1 may be formed on the first active pattern AP1. The first source/drain patterns SD1 may be provided in/on the first recesses RS1, respectively. The first source/drain patterns SD1 may be impurity regions of a first conductivity type (e.g., p-type). The first channel pattern CH1 may be interposed between a pair of adjacent first source/drain patterns SD1 from among the plurality of first source/drain patterns SD1. That is, the stacked first, second, and third semiconductor patterns SP1, SP2, and SP3 may connect (e.g., electrically connect) the pair of adjacent first source/drain patterns SD1 to each other.

A plurality of second source/drain patterns SD2 may be provided on the second active pattern AP2. The second source/drain patterns SD2 may be spaced apart from each other in the second direction D2. A plurality of second recesses RS2 may be formed on the second active pattern AP2. The second source/drain patterns SD2 may be provided in/on the second recesses RS2, respectively. The second source/drain patterns SD2 may be impurity regions of a second conductivity type (e.g., n-type). The second channel pattern CH2 may be interposed between a pair of adjacent second source/drain patterns SD2 from among the plurality of second source/drain patterns SD2. That is, the stacked first, second, and third semiconductor patterns SP1, SP2, and SP3 may connect (e.g., electrically connect) the pair of adjacent second source/drain patterns SD2 to each other.

The first and second source/drain patterns SD1 and SD2 may be epitaxial patterns formed through a selective epitaxial growth (SEG) process. For example, an upper surface of each of the first and second source/drain patterns SD1 and SD2 may be higher than an upper surface of the third semiconductor pattern SP3. As used herein, “an element A is higher than an element B” (or similar language such as “an element A has a higher level or a higher height than an element B”) means that the element A is farther than the element B from the upper surface and/or the lower surface of the substrate 100 in the third direction D3. As used herein, “an element A is lower than an element B” (or similar language such as “an element A has a lower level or a lower height than an element B”) means that the element A is closer than the element B to the upper surface and/or the lower surface of the substrate 100 in the third direction D3. For example, the upper surface of each of the first and second source/drain patterns SD1 and SD2 may be farther than the upper surface of the third semiconductor pattern SP3 from the upper surface of the substrate 100 in the third direction D3. In some example, an upper surface of at least one of the first and second source/drain patterns SD1 and SD2 may be positioned at substantially the same level (e.g., at the substantially the same distance from the upper surface of the substrate 100 in the third direction D3) as the upper surface of the third semiconductor pattern SP3.

In some embodiments of the present disclosure, a sidewall of the first source/drain pattern SD1 may have a bumpy embossed shape. That is, the sidewall of the first source/drain pattern SD1 may have a wavy (e.g., uneven, rough, or rugged) profile. The sidewall of the first source/drain pattern SD1 may protrude toward first, second, and third inner electrodes PO1, PO2, and PO3 of gate electrode GE, which will be described later.

Gate electrodes GE may be provided to overlap (e.g., cross) the first and second channel patterns CH1 and CH2 and extend in the first direction D1. The gate electrodes GE may be arranged in the second direction D2 with a first pitch. Each of the gate electrodes GE may overlap the first and second channel patterns CH1 and CH2, in the vertical direction (e.g., the third direction D3).

The gate electrode GE may include the first inner electrode PO1 interposed between each of the first and second active patterns AP1 and AP2 and the first semiconductor pattern SP1, the second inner electrode PO2 interposed between the first semiconductor pattern SP1 and the second semiconductor pattern SP2, the third inner electrode PO3 interposed between the second semiconductor pattern SP2 and the third semiconductor pattern SP3, and an outer electrode PO4 on the third semiconductor pattern SP3.

Referring to FIG. 2D, the gate electrode GE may be provided on an upper surface TS, a lower surface BS, and both (e.g., opposite) sidewalls SW of each of the first, second, and third semiconductor patterns SP1, SP2, and SP3. The gate electrode GE may extend around (e.g., surround or cover) the upper surface TS, the lower surface BS, and the both (e.g., the opposite) sidewalls SW of each of the first, second, and third semiconductor patterns SP1, SP2, and SP3. That is, a transistor according to the present embodiment may be a three-dimensional field effect transistor (e.g., MBCFET or GAAFET) in which the gate electrode GE extends around (e.g., surrounds or covers) the channel (e.g., the first and second channel patterns CH1 and CH2), including the semiconductor patterns (e.g., the first, second, and third semiconductor patterns SP1, SP2, and SP3) in three dimensions.

Referring back to FIGS. 1 and 2A to 2D, a pair of gate spacers GS may be respectively disposed on both (e.g., opposite) sidewalls of the outer electrode PO4 of the gate electrode GE. The gate spacers GS may extend in the first direction D1 along the gate electrode GE. Upper surfaces of the gate spacers GS may be higher than upper surfaces of the gate electrode GE (e.g., an upper surface of the outer electrode PO4). Upper surfaces of the gate spacers GS may be coplanar with an upper surface of a first interlayer insulating layer 110 to be described later. In some embodiments, the gate spacers GS may include, for example, SiCN, SiCON, and/or SiN. In some embodiments, the gate spacers GS may include a multi-layer, and the multi-layer may be made of, for example, at least two of SiCN, SiCON, and SiN.

A gate capping pattern GP may be provided on the gate electrode GE. The gate capping pattern GP may extend in the first direction D1 along the gate electrode GE. The gate capping pattern GP may include a material having etch selectivity with respect to first and second interlayer insulating layers 110 and 120 to be described later. In detail, the gate capping pattern GP may include, for example, SiON, SiCN, SiCON, and/or SiN.

A gate insulating layer GI may be interposed between the gate electrode GE and the first channel pattern CH1 and between the gate electrode GE and the second channel pattern CH2. The gate insulating layer GI may be on (e.g., cover) the upper surface TS, the lower surface BS, and the both (e.g., the opposite) sidewalls SW of each of the first, second, and third semiconductor patterns SP1, SP2, and SP3. The gate insulating layer GI may be on (e.g., cover) an upper surface of the device isolation layer ST. For example, the gate insulating layer GI may be between the upper surface of the device isolation layer ST and the gate electrode GE.

In some embodiments of the present disclosure, the gate insulating layer GI may include an interface layer and a high dielectric layer. The interface layer may include, for example, a silicon oxide layer and/or a silicon oxynitride layer. The high dielectric layer may include, for example, a high-k material having a higher dielectric constant than a silicon oxide layer. For example, the high dielectric layer may include, for example, hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

Referring back to FIG. 2B, inner spacers ISP may be provided on the second active pattern AP2. The inner spacers ISP may be interposed between the first, second, and third inner electrodes PO1, PO2, and PO3 of the gate electrode GE and the second source/drain pattern SD2, respectively. The inner spacers ISP may be in direct contact with the second source/drain pattern SD2. Each of the first, second, and third inner electrodes PO1, PO2, and PO3 of the gate electrode GE may be spaced apart from the second source/drain pattern SD2 by the inner spacers ISP.

Referring back to FIGS. 1 and 2A to 2D, the gate electrode GE may include a first metal pattern and a second metal pattern on the first metal pattern. The first metal pattern may be provided on the gate insulating layer GI and may be adjacent to the first, second, and third semiconductor patterns SP1, SP2, and SP3. The first metal pattern may include a work function metal for adjusting a threshold voltage of the transistor. A desired threshold voltage of the transistor may be achieved by adjusting the thickness and composition of the first metal pattern. For example, the first, second, and third inner electrodes PO1, PO2, and PO3 of the gate electrode GE may be formed of the first metal pattern that is the work function metal.

The first metal pattern may include, for example, a metal nitride layer. For example, the first metal pattern may include nitrogen (N) and at least one metal selected from the group consisting of titanium (Ti), tantalum (Ta), aluminum (Al), tungsten (W), and molybdenum (Mo). Furthermore, the first metal pattern may further include carbon (C). The first metal pattern may include a plurality of stacked work function metal layers.

The second metal pattern may include a metal having lower resistance than the first metal pattern. For example, the second metal pattern may include at least one metal selected from the group consisting of tungsten (W), aluminum (Al), titanium (Ti), and tantalum (Ta). The outer electrode PO4 of the gate electrode GE may include the first metal pattern and the second metal pattern on the first metal pattern.

A first interlayer insulating layer 110 may be provided on the epitaxial layer 101. The first interlayer insulating layer 110 may be on (e.g., cover) the gate spacers GS and the first and second source/drain patterns SD1 and SD2. An upper surface of the first interlayer insulating layer 110 may be substantially coplanar with an upper surface of the gate capping pattern GP and an upper surface of the gate spacer GS. A second interlayer insulating layer 120 may be disposed on the first interlayer insulating layer 110. The second interlayer insulating layer 120 may be on (e.g., cover) the gate capping pattern GP. A third interlayer insulating layer 130 may be provided on the second interlayer insulating layer 120. A fourth interlayer insulating layer 140 may be provided on the third interlayer insulating layer 130. For example, the first to fourth interlayer insulating layers 110 to 140 may include a silicon oxide layer.

A logic cell SHC may have a first boundary BD1 and a second boundary BD2 that face each other in the second direction D2. The first and second boundaries BD1 and BD2 may extend in the first direction D1. The logic cell SHC may have a third boundary BD3 and a fourth boundary BD4 that face each other in the first direction D1. The third and fourth boundaries BD3 and BD4 may extend in the second direction D2.

A pair of separation structures DB facing each other in the second direction D2 may be provided on both (e.g., opposite) sides of the logic cell SHC. For example, the pair of separation structures DB may be respectively provided on the first and second boundaries BD1 and BD2 of the logic cell SHC. The separation structure DB may extend parallel to the gate electrodes GE in the first direction D1. A pitch between the separation structure DB and the gate electrode GE adjacent thereto may be substantially the same as the first pitch.

The separation structure DB may pass through the gate capping pattern GP and the gate electrode GE and extend into the active patterns AP1 and AP2. The separation structure DB may pass through (e.g., penetrate) upper portions of each of the first and second active patterns AP1 and AP2. The separation structure DB may electrically separate an active region of the logic cell SHC from an active region of another adjacent cell.

Active contacts AC (e.g., a first lower active contact AC1_BP or a second lower active contact AC2_BP described later) electrically connected to the first and second source/drain patterns SD1 and SD2 may be provided through the first and second interlayer insulating layers 110 and 120, respectively. A pair of the active contacts AC may be provided on both (e.g., opposite) sides of the gate electrode GE, respectively. When viewed in a plan view, the active contact AC may have a bar shape extending in the first direction D1.

The active contact AC may be a self-aligned contact. That is, the active contact AC may be formed in a self-aligned manner using the gate capping pattern GP and the gate spacer GS. For example, the active contact AC may overlap (e.g., cover) at least a portion of the sidewall of the gate spacer GS. Although not shown, the active contact AC may overlap (e.g., at least partially cover) an upper surface of the gate capping pattern GP.

The active contacts AC may be arranged in the second direction D2 with the first pitch. That is, the pitch between the active contacts AC may be substantially the same as the first pitch between the gate electrodes GE.

A metal-semiconductor compound layer SC, for example, a silicide layer, may be interposed between the active contact AC and the first source/drain pattern SD1 and between the active contact AC and the second source/drain pattern SD2, respectively. The active contact AC may be electrically connected to the first and second source/drain patterns SD1 and SD2 through the metal-semiconductor compound layer SC. For example, the metal-semiconductor compound layer SC may include, for example, titanium-silicide, tantalum-silicide, tungsten-silicide, nickel-silicide, and/or cobalt-silicide.

Gate contacts GC electrically connected to the gate electrodes GE may be provided through the second interlayer insulating layer 120 and the gate capping pattern GP. When viewed in a plan view, the gate contacts GC may be disposed to overlap the first active pattern AP1 and the second active pattern AP2, respectively. For example, a gate contact GC may be provided on the second active pattern AP2 (refer to FIG. 2B).

In some embodiments of the present disclosure, referring to FIG. 2B, an upper portion of the active contact AC adjacent to the gate contact GC may be filled with an upper insulating pattern UIP. A lower surface of the upper insulating pattern UIP may be lower than a lower surface of the gate contact GC. That is, an upper surface of a conductive pattern FM and/or a barrier pattern BM (to be described later) of the active contact AC adjacent to the gate contact GC may be lower than the lower surface of the gate contact GC by the upper insulating pattern UIP. Accordingly, it is possible to prevent a problem in which a short circuit occurs due to contact between the gate contact GC and the active contact AC adjacent thereto.

Each of the active contact AC and gate contact GC may include the conductive pattern FM and the barrier pattern BM extending around (e.g., at least partially surrounding) the conductive pattern FM. For example, the conductive pattern FM may include aluminum, copper, tungsten, molybdenum, and/or cobalt. The barrier pattern BM may be on (e.g., cover) sidewalls and a lower surface of the conductive pattern FM. The barrier pattern BM may include, for example, a metal layer/metal nitride layer. The metal layer may include, for example, titanium, tantalum, tungsten, nickel, cobalt, and/or platinum. The metal nitride layer may include, for example, a titanium nitride layer (TiN), a tantalum nitride layer (TaN), a tungsten nitride layer (WN), a nickel nitride layer (NiN), a cobalt nitride layer (CON), and/or a platinum nitride layer (PtN).

A first metal layer M1 may be provided in the third interlayer insulating layer 130. For example, the first metal layer M1 may include a first power wiring M1_R1, a second power wiring M1_R2, and first wirings M1_I. Each of the wirings M1_R1, M1_R2, and M1_I of the first metal layer M1 may extend parallel to each other in the second direction D2.

In detail, the first and second power wirings M1_R1 and M1_R2 may be provided on the third and fourth boundaries BD3 and BD4 of the logic cell SHC, respectively. The first power wirings M1_R1 may extend in the second direction D2 along the third boundary BD3. The second power wiring M1_R2 may extend in the second direction D2 along the fourth boundary BD4.

The first wirings M1_I of the first metal layer M1 may be disposed between the first and second power wirings M1_R1 and M1_R2. The first wirings M1_I of the first metal layer M1 may be arranged in the first direction D1 with a second pitch. For example, the second pitch between the first wirings M1_I may be smaller than the first pitch. A line width of each of the first wirings M1_I may be smaller than a line width of each of the first and second power wirings M1_R1 and M1_R2.

The first metal layer M1 may further include first vias VI1. The first vias VI1 may be provided under the wirings M1_R1, M1_R2, and M1_I of the first metal layer M1, respectively. For example, the first vias VI1 may be disposed between the wirings of the first metal layer M1 (e.g., the first power wiring M1_R1, the second power wiring M1_R2, and the first wiring M1_I) and the active contact AC and/or between the wirings of the first metal layer M1 and the gate contact GC. The active contact AC and the wirings of the first metal layer M1 (e.g., the first power wiring M1_R1, the second power wiring M1_R2, and the first wiring M1_I) may be electrically connected to each other through the first via VI1. The gate contact GC and the wirings of the first metal layer M1 (e.g., the first power wiring M1_R1, the second power wiring M1_R2, and the first wiring M1_I) may be electrically connected to each other through the first via VI1.

The wirings of the first metal layer M1 (e.g., the first power wiring M1_R1, the second power wiring M1_R2, and the first wiring M1_I) and the first via VI1 therebelow may be formed through separate processes. That is, each of the wirings and the first via VI1 of the first metal layer M1 may be formed through a single damascene process. The manufacturing processes of the wirings and the first via VI1 of the first metal layer M1, however, are not limited thereto. The semiconductor device according to some embodiments of the present disclosure may be formed using a process of less than 20 nanometers (nm).

A second metal layer M2 may be provided in the fourth interlayer insulating layer 140. The second metal layer M2 may include a plurality of second wirings M2_I. Each of the second wirings M2_I of the second metal layer M2 may have a line shape or a bar shape extending in the first direction D1. That is, the second wirings M2_I may extend parallel to each other in the first direction D1.

The second metal layer M2 may further include second vias VI2 provided under the second wirings M2_I. For example, the second vias VI2 may be disposed between the second wirings M2_I and the wrings of the first metal layer M1 (e.g., the first power wiring M1_R1, the second power wiring M1_R2, and the first wiring M1_I). A wiring of the first metal layer M1 (e.g., the first power wiring M1_R1, the second power wiring M1_R2, and the first wiring M1_I) and a wiring of the second metal layer M2 (e.g., the second wiring M2_I) may be electrically connected to each other through the second via VI2. In some embodiments, the wiring of the second metal layer M2 (e.g., the second wiring M2_I) and the second via VI2 therebelow may be formed together through a dual damascene process. The manufacturing processes of the wirings and the second via VI2 of the second metal layer M2, however, are not limited thereto.

The wirings of the first metal layer M1 (e.g., the first power wiring M1_R1, the second power wiring M1_R2, and the first wiring M1_I) and the wirings of the second metal layer M2 (e.g., the second wiring M2_I) may include the same or different conductive materials. For example, the wirings of the first metal layer M1 and the wirings of the second metal layer M2 may include at least one metal material selected from aluminum, copper, tungsten, molybdenum, ruthenium, and cobalt. Although not shown, metal layers (e.g., M3, M4, M5, etc.) stacked on the fourth interlayer insulating layer 140 may be additionally disposed. Each of the stacked metal layers may include wirings for routing between cells.

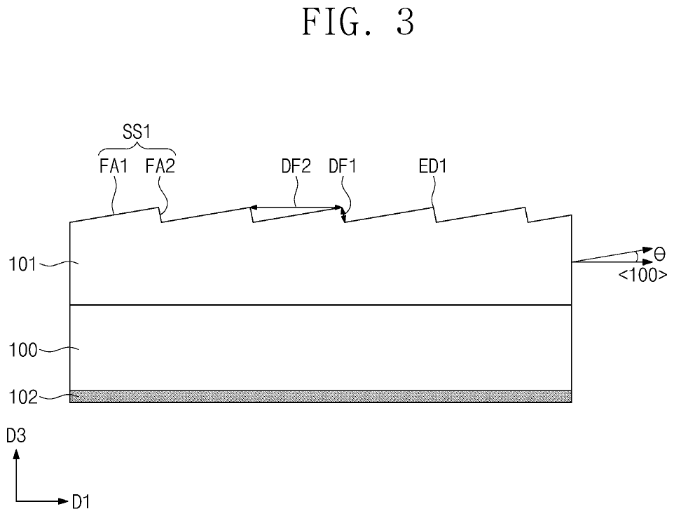

FIG. 3 is an enlarged view of a portion ‘CU1’ of FIG. 2D. Descriptions of portions overlapping with those of FIGS. 2A to 2D may be omitted. Referring to FIG. 3, an upper surface of the epitaxial layer 101 may include a shape of a first surface pattern SS1. Although not shown, a lower surface of the epitaxial layer 101 may include a surface pattern having substantially the same shape as the shape of the first surface pattern SS1. The first surface pattern SS1 may include a plurality of first surfaces FA1 arranged in the first direction D1 to have a first step DF1 and second surfaces FA2 respectively connecting thereto. In this specification, the first step DF1 may be referred to as a height of the second surface FA2. The first direction D1 may be a <100> direction. A level (e.g., a height) of the first step DF1 may correspond to a level (e.g., a height) difference between adjacent first surfaces FA1. The height of the first step DF1 may range from 1.9 Å to 38 Å. The number of first surfaces FA1 may be two or more.

The first surface pattern SS1 may include a first surface FA1 and a second surface FA2 adjacent to and connected to the first surface FA1. In detail, the first surface FA1 may be connected to the second surface FA2 through a first edge ED1 included in the first surface FA1. A plurality of first edges ED1 may be provided in a repeatedly protruding form. For example, the plurality of first edges ED1 may protrude from the upper and/or lower surface of the epitaxial layer 101. That is the plurality of first edges ED1 may constitute the highest points of the upper surface or the lowest points of the lower surface of the epitaxial layer 101. A distance between the adjacent first edges ED1 may range from 20 nm to 300 nm.

The upper surface of the substrate 100 may be referred to as a main surface MS in this specification. The upper surface of the substrate 100 (e.g., the main surface MS) may be inclined from the {110} crystal plane by a crystal off angle θ. The epitaxial layer 101 may be disposed on the inclined main surface MS.

The crystal off angle θ may be 0° to 5°. Although not shown, when the crystal off angle θ is 0°, the first surface pattern SS1 and a second surface pattern SS2 described later may not be included on the epitaxial layer 101, the first channel pattern CH1 and the second channel pattern CH2. Meanwhile, the main surface MS may be tilted by a direction off angle θ ′ in the <100> direction with respect to the {110} crystal plane and may be inclined by the crystal off angle θ. The direction off angle θ′ may be 30° or less.

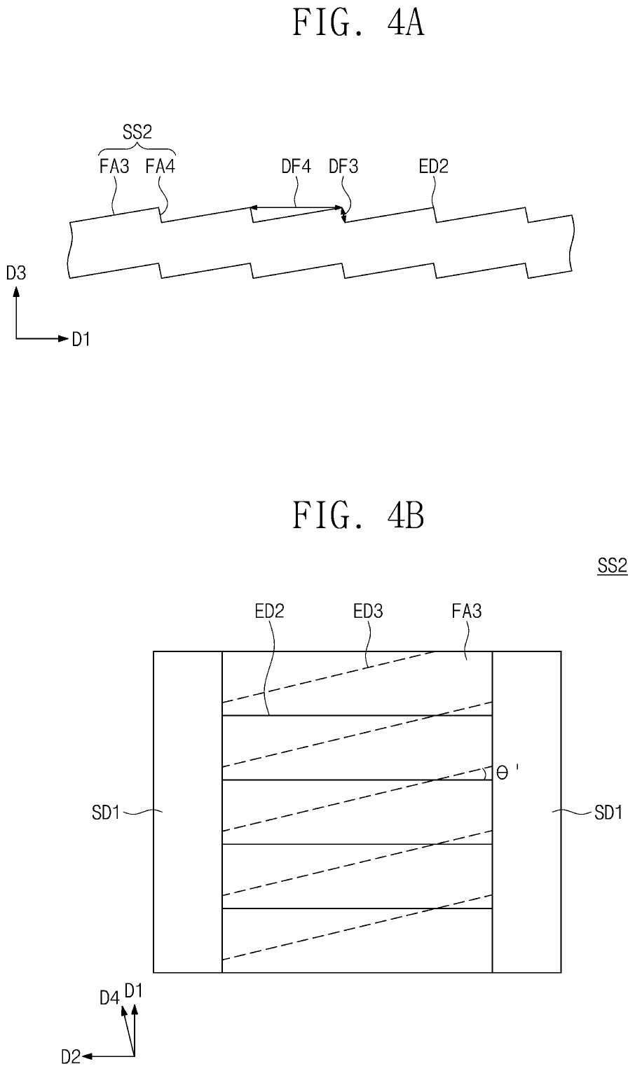

FIG. 4A is an enlarged view of first, second, and third semiconductor patterns SP1, SP2, and SP3 included in a first channel pattern CH1 and a second channel pattern CH2.

Referring to FIG. 4A, upper surfaces of the first to third semiconductor patterns SP1 to SP3 may include a shape of a second surface pattern SS2. Bottom surfaces of the first to third semiconductor patterns SP1 to SP3 may have substantially the same shape as the shape of the second surface pattern SS2. The second surface pattern SS2 may include a plurality of third surfaces FA3 arranged in the first direction D1 to have a second step DF3 and fourth surfaces FA4 respectively connecting thereto. In the present specification, the second step DF3 may be a height of the fourth surface FA4. The first direction D1 may be a <100> direction. The length of second step DF3 (e.g., the height of the fourth surface FA4) may range from 1.9 Å to 38 Å. The number of third surfaces FA3 may be two or more.

The second surface pattern SS2 may include a third surface FA3 and a fourth surface FA4 adjacent to and connected to the third surface FA3. In detail, the third surface FA3 may be connected to the fourth surface FA4 through an second edge ED2 included in the third surface FA3. A plurality of second edges ED2 may be provided in a repeatedly protruding form. A distance between the adjacent second edges ED2 may range from 20 nm to 300 nm.

A moving direction of carriers electrically connecting the first and second channel patterns CH1 and CH2 and the first and second source/drain patterns SD1 and SD2 may be the second direction D2. The moving direction of carriers may be referred to as a carrier moving direction. The carrier moving direction may mean a net direction to which the carriers move. For example, when a majority of carriers are moving in a specific direction, the specific direction may be referred to as the carrier moving direction. The second direction D2 may be a <110> direction.

FIG. 4B is a plan view illustrating a first channel pattern CH1 for explaining some embodiments of the present disclosure. A description overlapping with that of FIG. 4A may be omitted. Although not shown, the second channel pattern CH2 may also have a second surface pattern SS2 having substantially the same shape as a structure of a first channel pattern CH1 to be described later. Referring to FIG. 4B, an arrangement direction of the second surface pattern SS2 may be in a fourth direction D4 different from the first and second directions D1 and D2. That is, the second surface pattern SS2 according to some embodiments may be disposed in a form in which a third edge ED3 repeatedly protrudes is the fourth direction D4 to have a direction different from that of the second edge ED2. The third edge ED3 may connect the third and fourth surfaces FA3 and FA4 (refer to FIG. 4A). The fourth direction D4 may be the same as the first direction D1 or may form a direction off angle θ′ with the first direction D1, and the direction off angle θ′ may have an angle of a range of 30° or less. According to this structure, an arrangement direction of the second surface pattern SS2 and a moving direction of the carriers may have an angle of a range of 90° to 30° or less from 90°, and when the third edge ED3 is arranged in the fourth direction D4, an angle formed between the third edge ED3 and the second edge ED2 may also be the same as the direction off angle θ′.

In the semiconductor device according to the comparative example, a substrate may have a {100} crystal plane and a moving direction of carriers in a channel may have <110>. In the semiconductor device according to the comparative example, the mobility of electrons in the channel pattern may be 380 cm²/V·s, and the mobility of holes in the channel pattern may be 80 cm²/V·s, which is lower than the mobility of electrons. Therefore, the length of the channel included in the PMOSFET region needs to be increased to compensate for the hole mobility, which causes a problem in that a scaling of the semiconductor device needs to be increased.

On the other hand, in the semiconductor device according to the embodiments of the present disclosure, a substrate 100 and the epitaxial layer 101 on the substrate 100 have a {110} crystal plane, and a moving direction of carriers in a channel may have a <110>. That is, in the semiconductor device according to some embodiments of the present disclosure, a mobility of electrons in the channel pattern is, for example, 280 cm²/V s, and a mobility of holes in the channel pattern is 190 cm²/V s, and thus there is less need (e.g., no need) to increase the length of the channel of the PMOSFET to compensate for the hole mobility. Also, in the first channel pattern CH1 and the second channel pattern CH2, the moving direction of the carriers corresponds to the <110>. As a result, carriers in the channel (e.g., the first channel pattern CH1 and the second channel pattern CH2) may not tend to move toward (e.g., may be prevented from moving toward) the second edges ED2 disposed (e.g., arranged) in the <100> direction on the third surfaces FA3, thereby reducing carriers from colliding with the second edges ED2. Therefore, surface scattering effect may be reduced (e.g., minimized), thereby improving electrical characteristics of the semiconductor device.

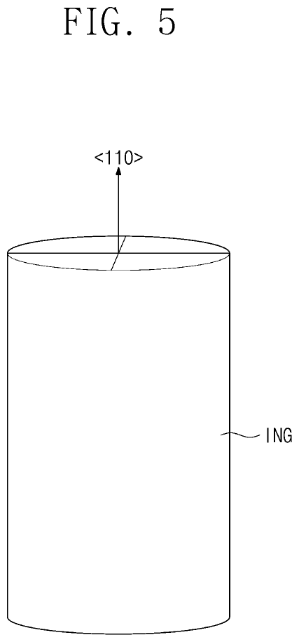

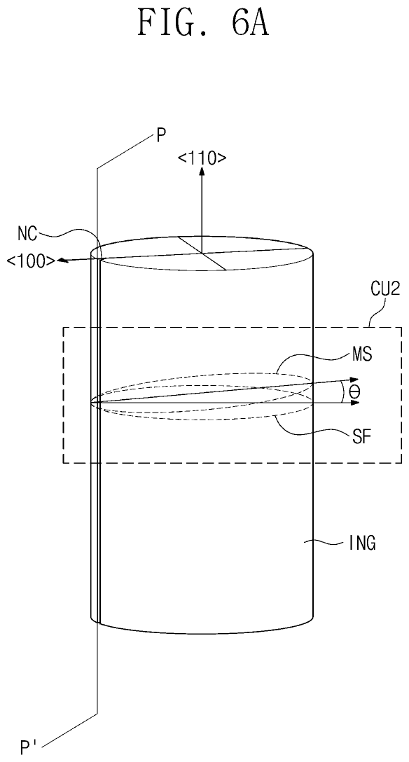

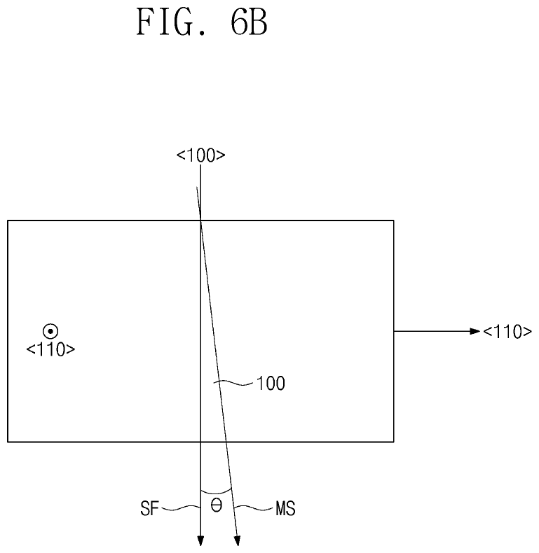

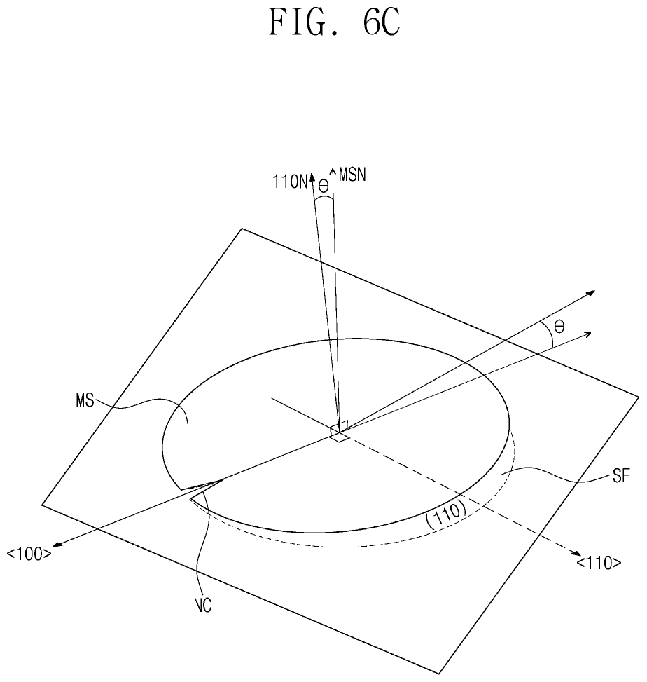

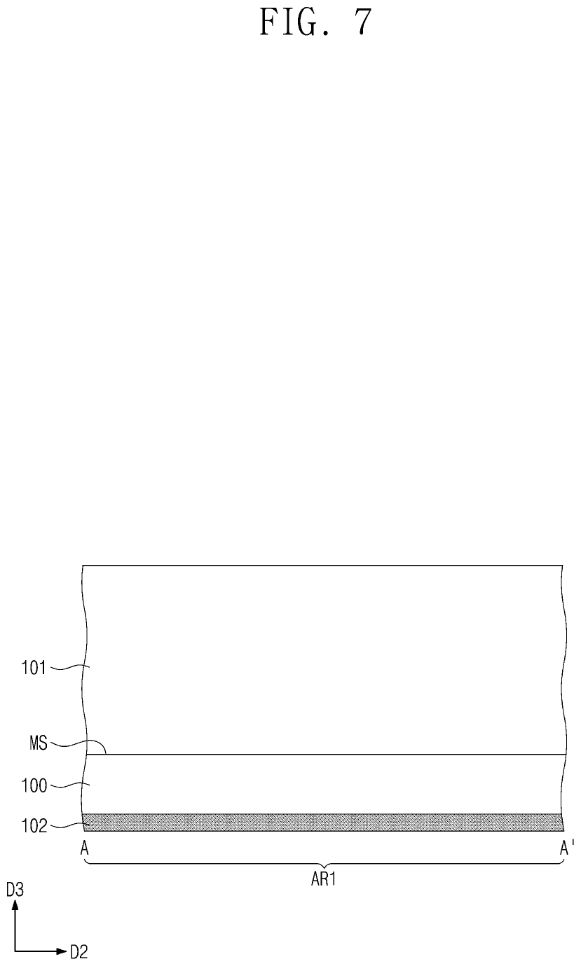

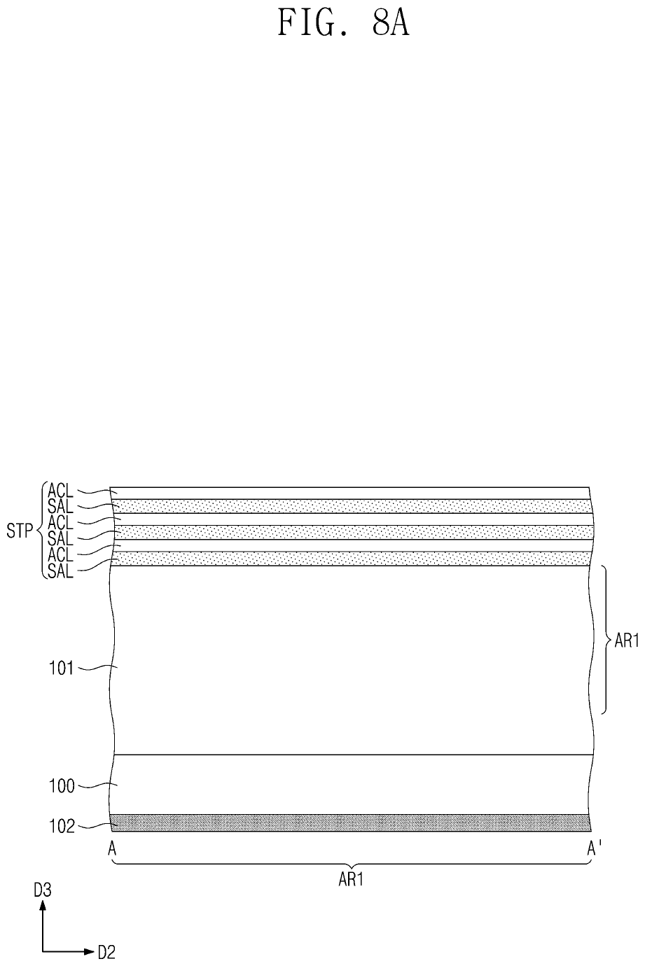

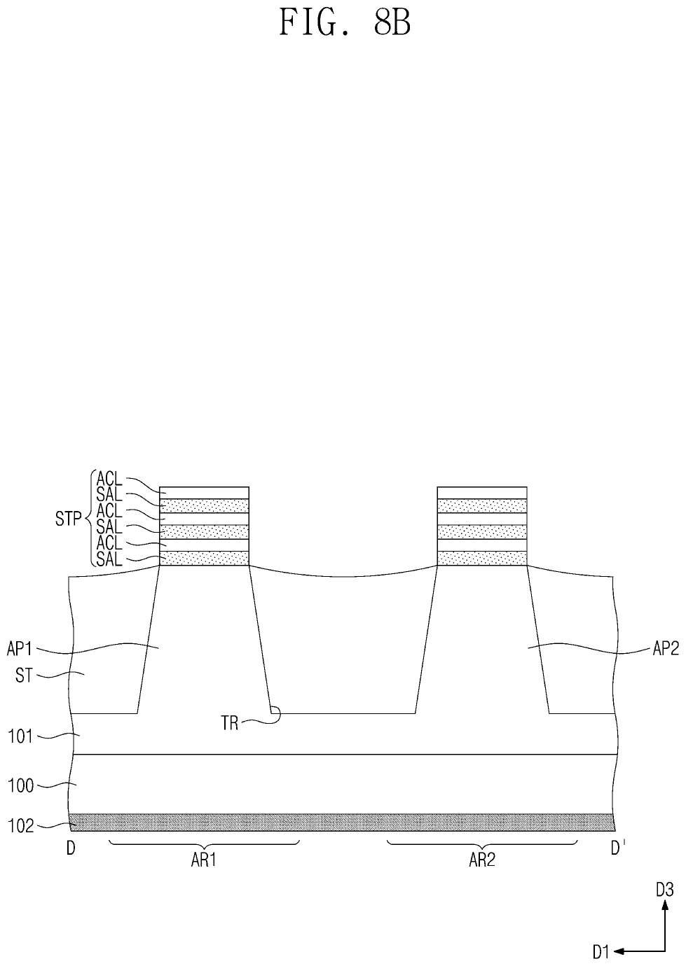

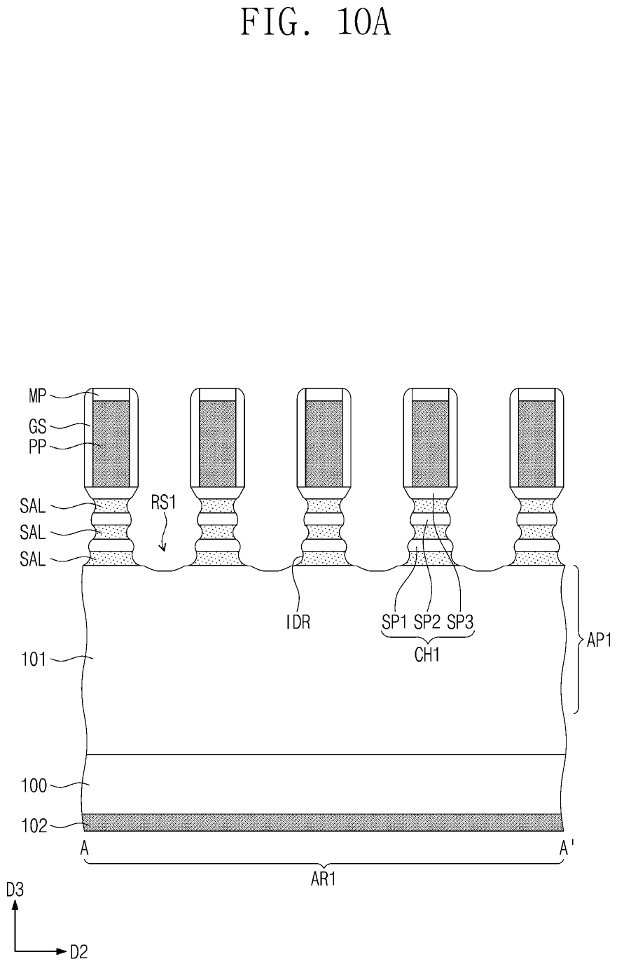

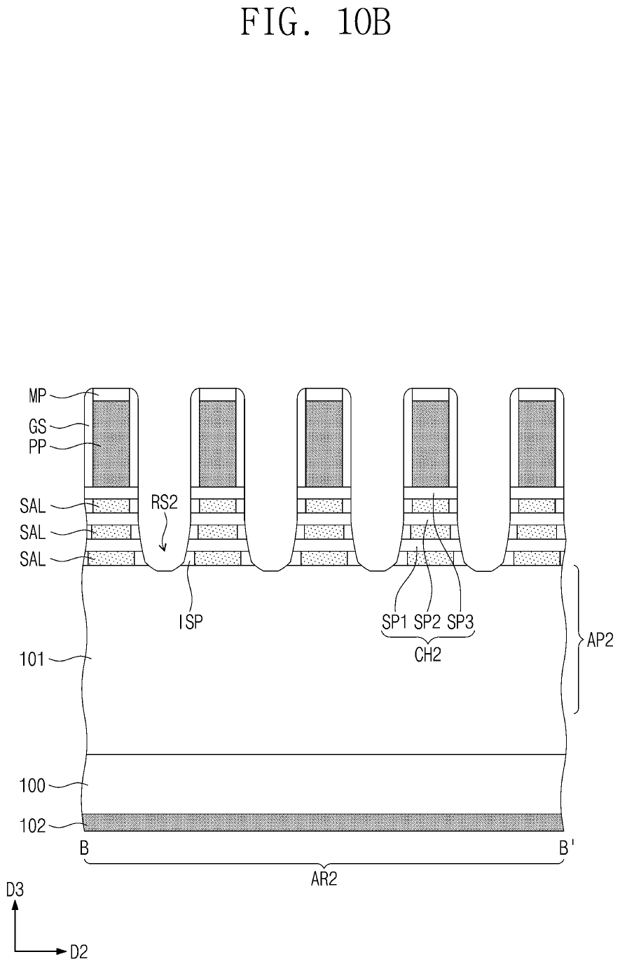

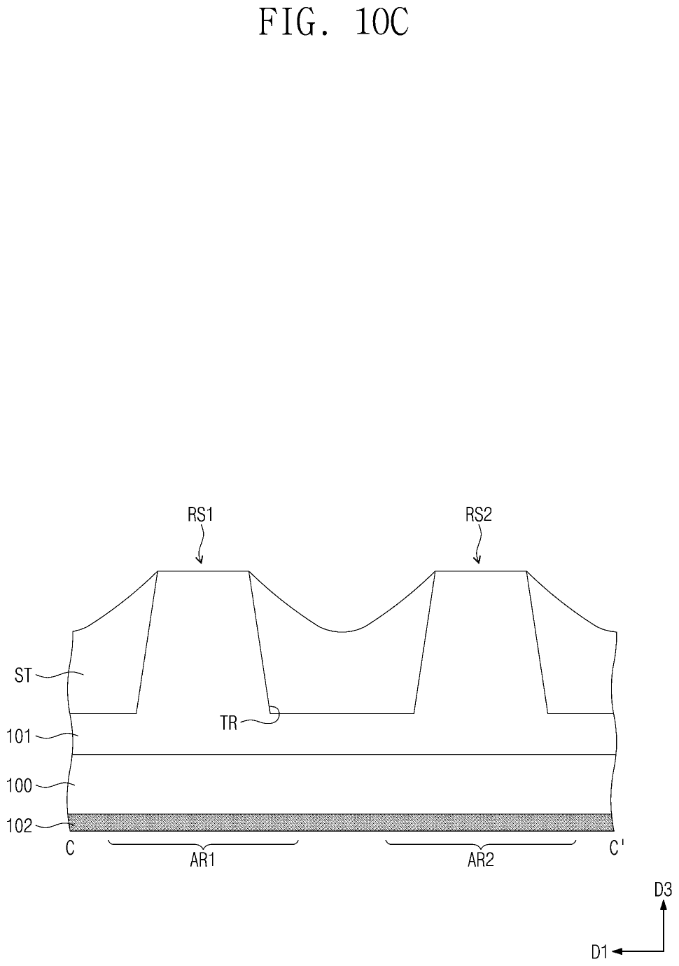

FIGS. 5 to 14C are views illustrating a method of manufacturing a semiconductor device according to some embodiments of the present disclosure. In detail, FIGS. 5 and 6A, 6B, and 6C are views illustrating a manufacturing method of the substrate 100, FIG. 6B is a cross-sectional view taken along line P-P′ of FIG. 6A, and FIG. 6C is an enlarged view of portion ‘CU2’ of FIG. 6A. FIGS. 7, 8A, 9A, 10A, 11A, 12A, 13A, and 14A are cross-sectional views corresponding to line A-A′ of FIG. 1. FIGS. 10B, 11B, 12B, 13B, and 14B are cross-sectional views corresponding to line B-B′ of FIG. 1. FIGS. 10C, 11C, 12C, 13C, and 14C are cross-sectional views corresponding to line C-C′ of FIG. 1. FIGS. 8B, 9B, 12D, and 13D are cross-sectional views corresponding to line D-D′ of FIG. 1.

Referring to FIG. 5, an ingot ING having a {110} crystal plane may be provided. The ingot ING may be formed into a cylindrical ingot ING by a crystal growth manner such as a Czochralski (CZ) manner. Although not shown, the ingot ING may be formed by inserting polycrystalline silicon into a quartz crucible, heating and melting a graphite heating element by a heater disposed on a side of the crucible, and then immersing of seed crystals in the silicon melt formed as a result of the melting. Here, the seed crystal may have a {110} crystal plane. Thereafter, crystallization may occur at the silicon melt interface and may rotate and pull up the seed crystal, to form a single crystal silicon ingot (the ingot ING) having a {110} crystal plane.

Referring to FIGS. 6A to 6C, a notch NC may be formed in a <100> direction on the ingot ING. Thereafter, the ingot ING may be repeatedly sliced in a slicing plane at an angle inclined by a crystal off angle θ with respect to the {110} crystal plane to form a substrate 100. The crystal off angle θ may be 0° to 5°. Through the slicing process, a main surface MS, which is an upper surface of the substrate 100, and a reference surface SF may be inclined by the crystal off angle θ. An angle formed by a normal vector 110N of the reference plane SF and a normal vector MSN of the main surface MS may also be the same as the crystal off angle θ.

Shapes of the first surface pattern SS1 shown in FIG. 3 and the second surface pattern SS2 shown in FIG. 4 may be changed depending on values of the crystal off angle θ and the direction off angle θ′. That is, a distance between the first surfaces FA1 included in the first surface pattern SS1 and a distance between the third surfaces FA3 included in the second surface pattern SS2 may be determined by the value of the crystal off angle θ. As the crystal off angle θ increases, the distance between the first surfaces FA1 and the distance between the third surfaces FA3 may increase. Also, an arrangement direction of the first surface pattern SS1 and the second surface pattern SS2 may be determined by the value of the direction off angle θ′. Meanwhile, when the crystal off angle θ is 0°, although not shown, the present disclosure may not include the first surface pattern SS1 and the second surface pattern SS2.

Referring to FIG. 7, a diffusion barrier layer 102 may be formed on a lower surface of the substrate 100 formed through the above-described slicing process. The diffusion barrier layer 102 may have a thickness of 40 Å or more. Thereafter, an epitaxial process may be performed on the main surface MS of the substrate 100 to form an epitaxial layer 101. The epitaxial process may include a chemical vapor deposition (CVD) process or a molecular beam epitaxy (MBE) process.

Referring to FIGS. 8A and 8B, the epitaxial layer 101 may include first and second active regions AR1 and AR2. Active layers ACL and sacrificial layers SAL may be alternately deposited on the epitaxial layer 101. The active layers ACL may include, for example, one of silicon (Si), germanium (Ge), and silicon-germanium (SiGe), and the sacrificial layers SAL may include, for example, another one of silicon (Si), germanium (Ge), and silicon-germanium (SiGe).

The sacrificial layer SAL may include a material having an etch selectivity with respect to the active layer ACL. For example, the active layers ACL may include silicon (Si), and the sacrificial layers SAL may include silicon-germanium (SiGe). A concentration of germanium (Ge) in each of the sacrificial layers SAL may be 10 at % to 30 at %.

Mask patterns may be respectively formed on the first and second active regions AR1 and AR2 of the epitaxial layer 101. The mask pattern may have a line shape or a bar shape extending in the second direction D2.

A patterning process may be performed using the mask patterns as an etch mask to form a trench TR defining first and second active patterns AP1 and AP2. The first active pattern AP1 may be formed on the first active region AR1. The second active pattern AP2 may be formed on the second active region AR2.

A stacked pattern STP may be formed on each of the first and second active patterns AP1 and AP2. The stacked pattern STP may include active layers ACL and sacrificial layers SAL that are alternately stacked with each other. The stacked pattern STP may be formed together with the first and second active patterns AP1 and AP2 during the patterning process.

A device isolation layer ST may be formed to at least partially fill the trench TR. In detail, an insulating layer may be formed on an upper surface (e.g., the entire upper surface) of the epitaxial layer 101 to cover the first and second active patterns AP1 and AP2 and the stacked patterns STP. The device isolation layer ST may be formed by recessing the insulating layer until the stacked patterns STP are exposed.

The device isolation layer ST may include an insulating material such as a silicon oxide layer. The stacked patterns STP may be exposed on the device isolation layer ST. That is, the stacked patterns STP may vertically protrude from the device isolation layer ST.

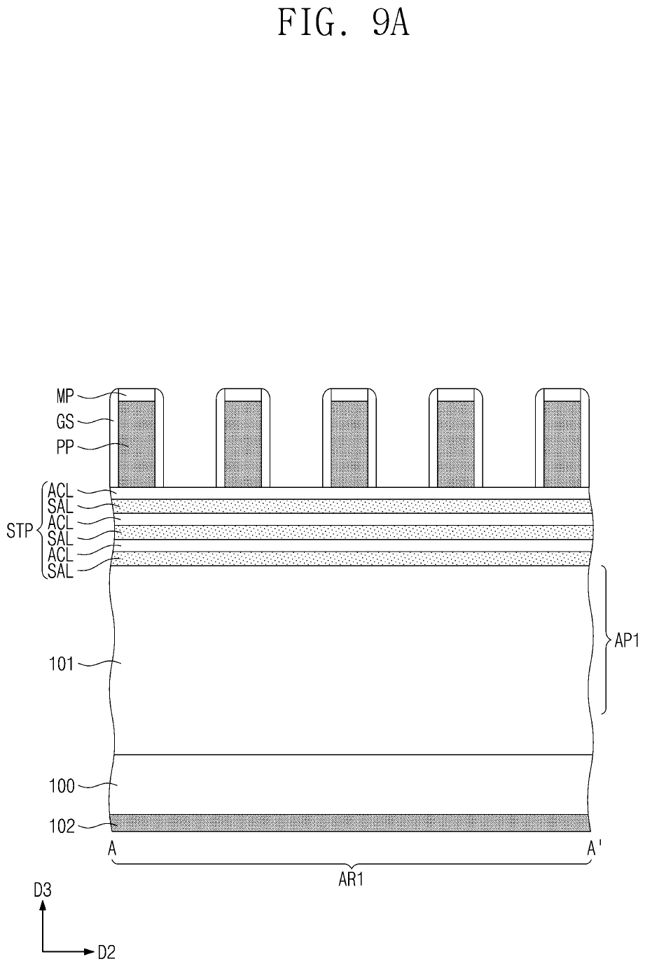

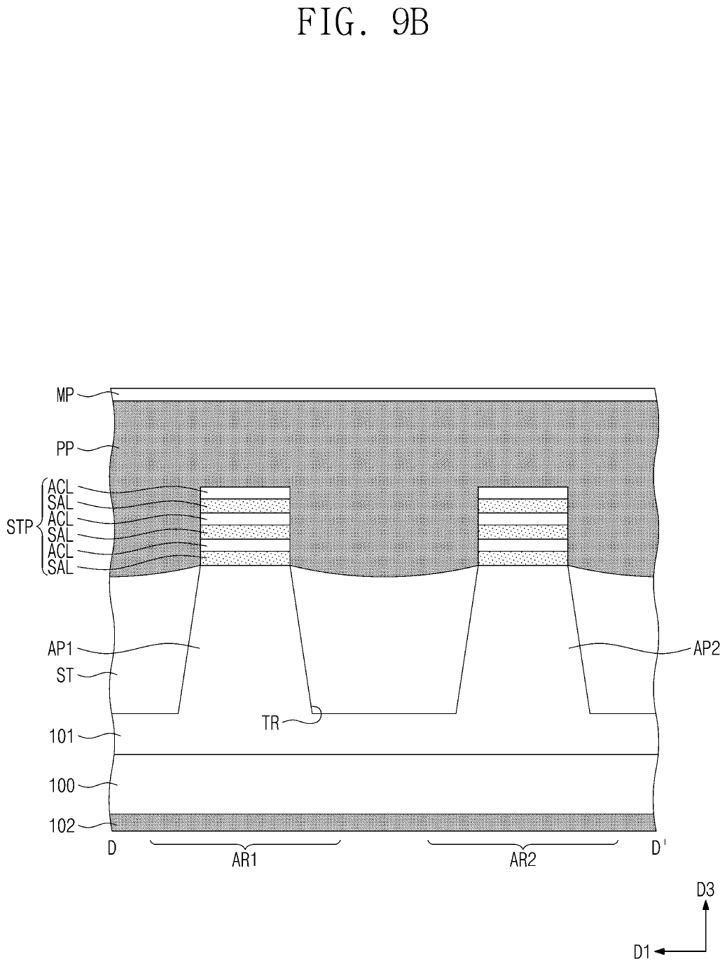

Referring to FIGS. 9A and 9B, sacrificial patterns PP crossing the stacked patterns STP may be formed on the epitaxial layer 101. Each of the sacrificial patterns PP may be formed in a line shape or bar shape extending in the first direction D1. The sacrificial patterns PP may be arranged in the second direction D2 with a first pitch.

In detail, forming the sacrificial patterns PP may include forming a sacrificial layer on the upper surface (e.g., the entire upper surface) of the epitaxial layer 101, forming hard mask patterns MP on the sacrificial layer, and patterning the sacrificial layer using the hard mask patterns MP as an etch mask. The sacrificial layer may include, for example, polysilicon.

A pair of gate spacers GS may be formed on both (e.g., opposite) sidewalls of each of the sacrificial patterns PP. Forming the gate spacers GS may include conformally forming a gate spacer layer on the upper surface (e.g., the entire upper surface) of the epitaxial layer 101 and anisotropically etching the gate spacer layer. In some embodiments of the present disclosure, the gate spacer GS may be a multi-layer including at least two layers.

Referring to FIGS. 10A to 10C, first recesses RS1 may be formed in the stacked pattern STP on the first active pattern AP1. Second recesses RS2 may be formed in the stacked pattern STP on the second active pattern AP2. While the first and second recesses RS1 and RS2 are formed, the device isolation layer ST on both (e.g., opposite) sides of each of the first and second active patterns AP1 and AP2 may be further recessed (refer to FIG. 10C).

In detail, the stacked pattern STP on the first active pattern AP1 may be etched using the hard mask patterns MP and the gate spacers GS as an etch mask to form the first recesses RS1. The first recess RS1 may be formed between a pair of sacrificial patterns PP.

From the active layers ACL, first, second, and third semiconductor patterns SP1, SP2, and SP3 sequentially deposited between adjacent first recesses RS1 may be formed, respectively. The first, second, and third semiconductor patterns SP1, SP2, and SP3 between the adjacent first recesses RS1 may constitute a first channel pattern CH1.

The sacrificial layers SAL may be exposed by the first recess RS1. A selective etching process may be performed on the exposed sacrificial layers SAL. The selective etching process may include a wet etching process for selectively removing only, for example, silicon-germanium of the sacrificial layers SAL. Each of the sacrificial layers SAL may be indented by the selective etching process to form an indent region IDR. A sidewall of the sacrificial layer SAL may be concave by the indent region IDR. An insulating layer may be formed in the first recess RS1 to fill the indent regions IDR. The first, second, and third semiconductor patterns SP1, SP2, and SP3 exposed by the first recess RS1 and the sacrificial layers SAL may serve as a seed layer of the insulating layer. The insulating layer may be grown as a crystalline dielectric layer on a crystalline semiconductor constituting the first, second, and third semiconductor patterns SP1, SP2, and SP3 and the sacrificial layers SAL.

An inner spacer ISP may be formed to fill the indent region IDR. In detail, forming the inner spacer ISP may include wet etching the epitaxial dielectric layer (e.g., the insulating layer described above) until sidewalls of the first, second, and third semiconductor patterns SP1, SP2, and SP3 are exposed. As a result, the epitaxial dielectric layer (e.g., the insulating layer described above) may remain only in the indent region IDR to constitute the inner spacer ISP.

Referring back to FIGS. 10A to 10C, the second recesses RS2 in the stacked pattern STP on the second active pattern AP2 may be formed in a similar manner to forming the first recesses RS1. A selective etching process may be performed on the sacrificial layers SAL exposed by the second recess RS2. The second recess RS2 may have a wavy inner wall by the indent regions IDR. Inner spacers ISP may not be formed in the indent regions IDR on the second active pattern AP2. The first, second, and third semiconductor patterns SP1, SP2, and SP3 between adjacent second recesses RS2 may constitute a second channel pattern CH2. A width of the second recess RS2 in the second direction D2 may decrease as the second recess RS2 approaches the substrate 100.

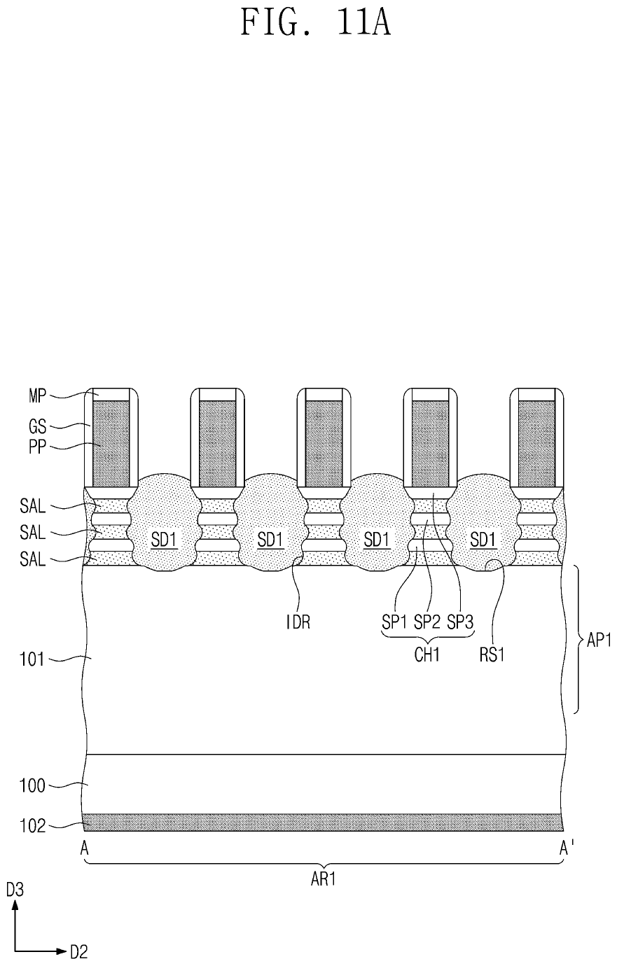

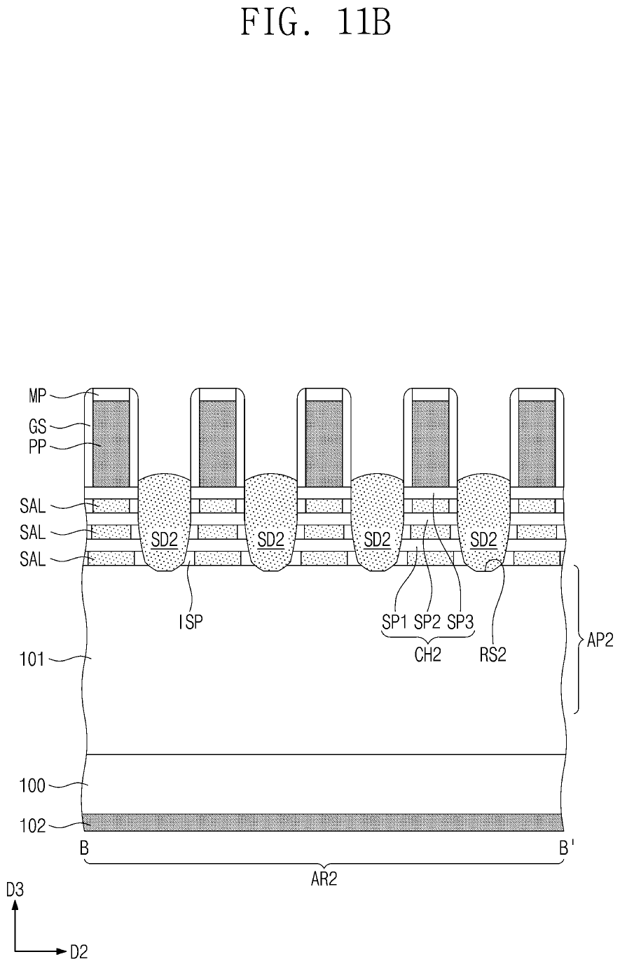

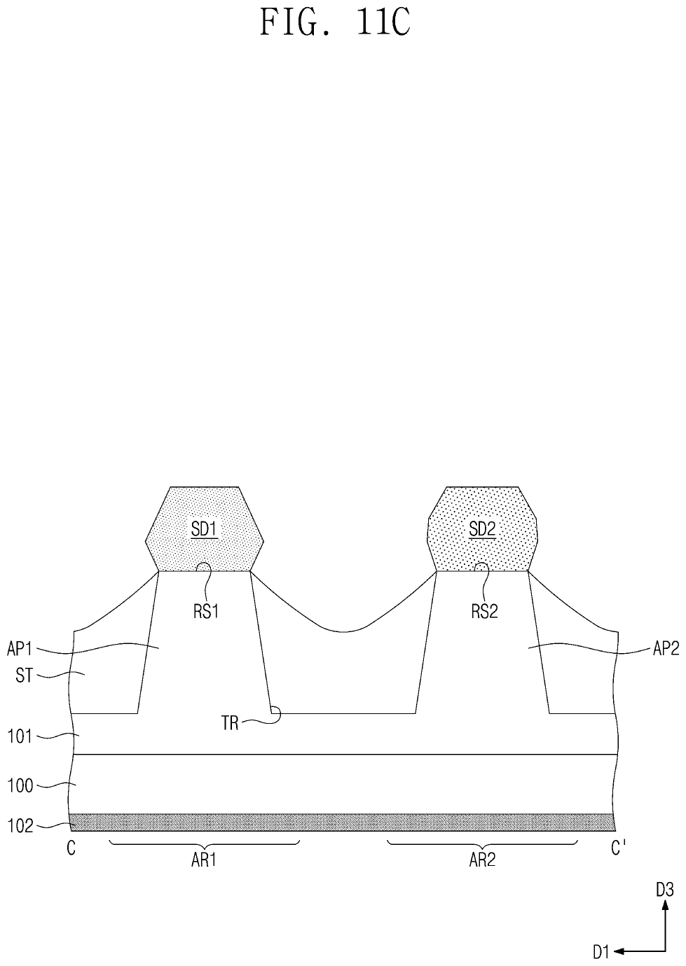

Referring to FIGS. 11A to 11C, first source/drain patterns SD1 may be formed in the first recesses RS1, respectively. In detail, an SEG process may be performed using an inner wall of the first recess RS1 as a seed layer to form an epitaxial layer (the first source/drain patterns SD1) filling the first recess RS1. The epitaxial layer may be grown using the substrate 100 and the first, second, and third semiconductor patterns SP1, SP2, and SP3 exposed by the first recess RS1 as seeds. For example, the SEG process may include a chemical vapor deposition (CVD) process or a molecular beam epitaxy (MBE) process.

As an embodiment, the first source/drain pattern SD1 may include the same semiconductor element (e.g., Si) as the substrate 100. While the first source/drain pattern SD1 is formed, an impurity (e.g., boron, gallium, or indium) that causes the first source/drain pattern SD1 to have a p-type may be in-situ implanted. In some embodiments, the impurity may be implanted into the first source/drain pattern SD1 after the first source/drain pattern SD1 is formed.

Second source/drain patterns SD2 may be formed in the second recesses RS2, respectively. In detail, a SEG process may be performed using the inner wall of the second recess RS2 as a seed layer to form the second source/drain pattern SD2.

As an embodiment, the second source/drain pattern SD2 may include a semiconductor element (e.g., SiGe) having a lattice constant greater than that of the semiconductor element of the substrate 100. While the second source/drain pattern SD2 is formed, an impurity (e.g., phosphorus, arsenic, or antimony) that causes the second source/drain pattern SD2 to have an n-type may be implanted in-situ. In some embodiments, the impurity may be implanted into the second source/drain pattern SD2 after the second source/drain pattern SD2 is formed.

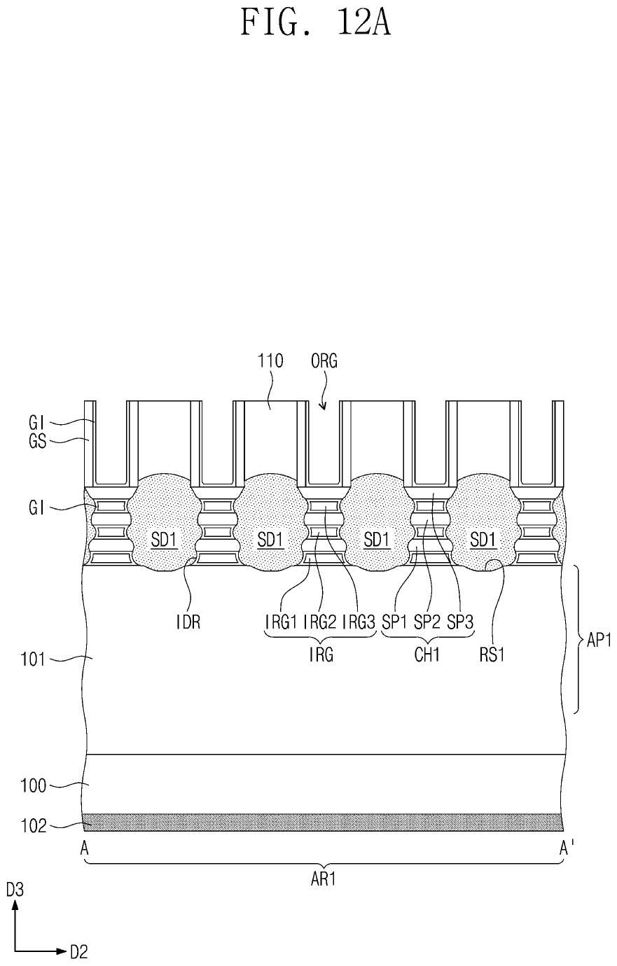

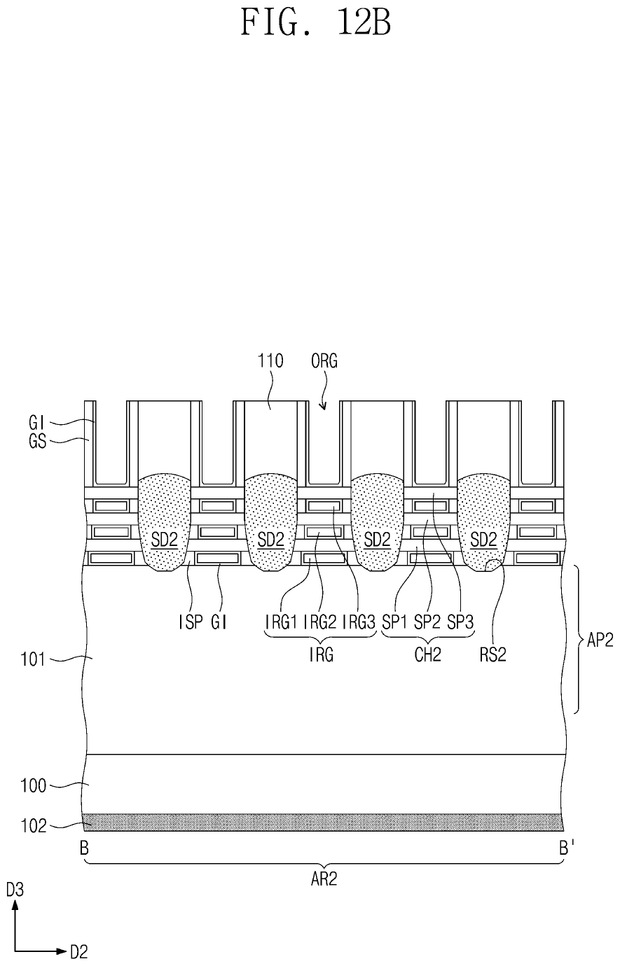

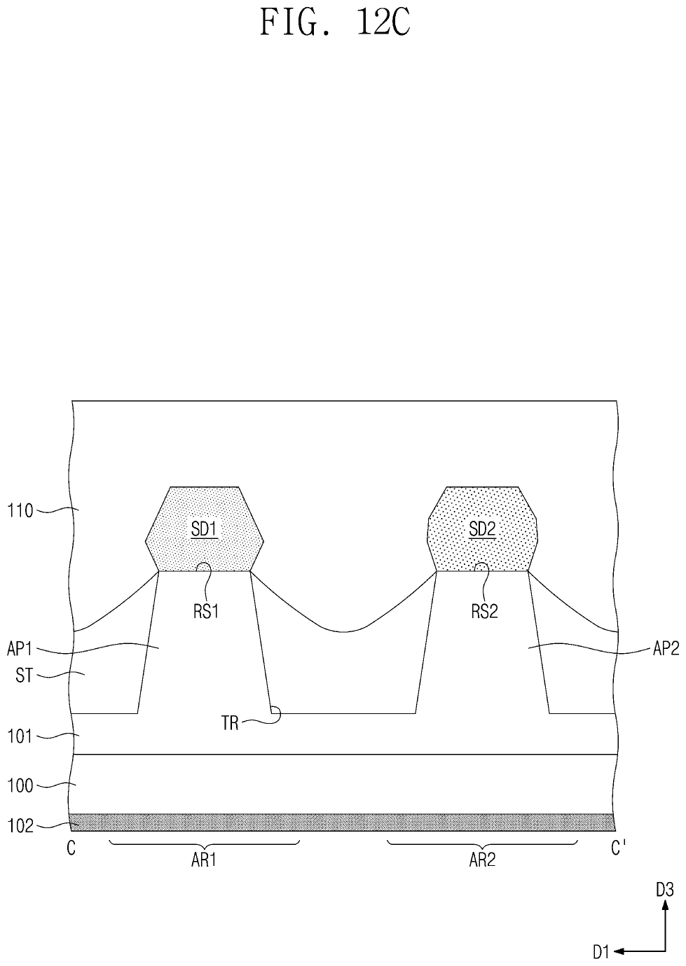

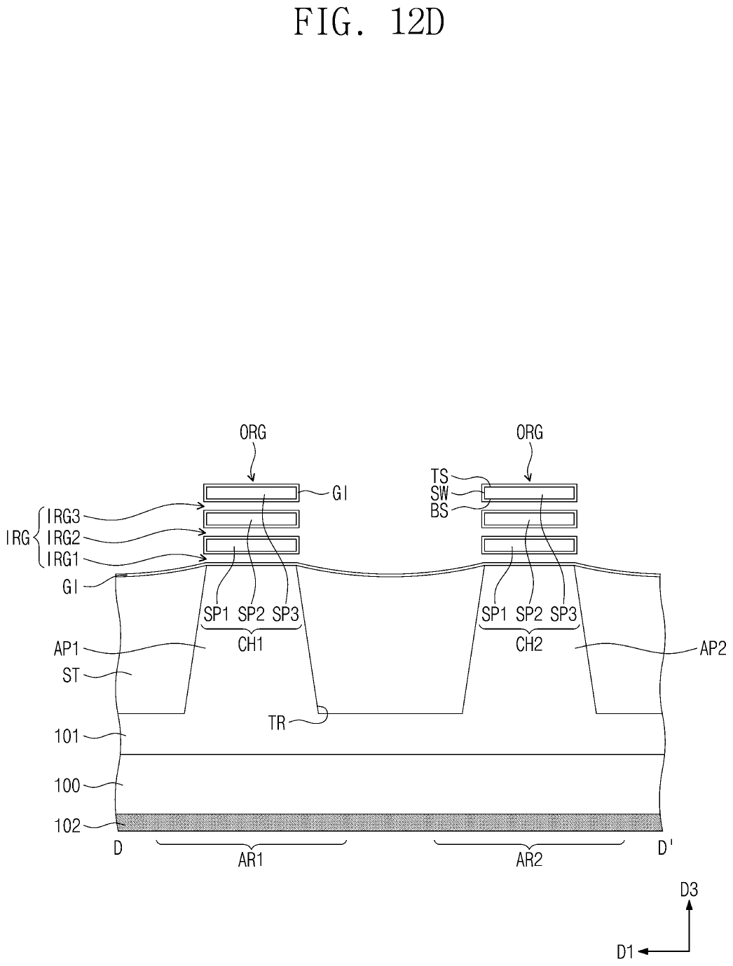

Referring to FIGS. 12A to 12D, a first interlayer insulating layer 110 may be formed on (e.g., to cover) the first and second source/drain patterns SD1 and SD2, the hard mask patterns MP, and the gate spacers GS. For example, the first interlayer insulating layer 110 may include a silicon oxide layer.

The first interlayer insulating layer 110 may be planarized until upper surfaces of the sacrificial patterns PP are exposed. Planarization of the first interlayer insulating layer 110 may be performed using an etch back or chemical mechanical polishing (CMP) process. During the planarization process, all of the hard mask patterns MP may be removed. As a result, the upper surface of the first interlayer insulating layer 110 may be coplanar with the upper surfaces of the sacrificial patterns PP and the upper surfaces of the gate spacers GS.

The exposed sacrificial patterns PP may be selectively removed. By removing the sacrificial patterns PP, an outer region ORG exposing the first and second channel patterns CH1 and CH2 may be formed (refer to FIG. 12D). Removing the sacrificial patterns PP may include wet etching using an etchant that selectively etches polysilicon.

The sacrificial layers SAL exposed through the outer region ORG may be selectively removed to form inner regions IRG (refer to FIG. 12D). In detail, an etching process for selectively etching the sacrificial layers SAL may be performed to remove only the sacrificial layers SAL while leaving the first, second, and third semiconductor patterns SP1, SP2, and SP3 remain (e.g., intact). The etching process may have a high etching rate for silicon-germanium having a relatively high germanium concentration. For example, the etching process may have a high etching rate for silicon-germanium having a germanium concentration greater than 10 at %.

During the etching process, the sacrificial layers SAL on the first and second active regions AR1 and AR2 may be removed. The etching process may be wet etching. An etching material used in the etching process may quickly remove the sacrificial layer SAL having a relatively high germanium concentration.

Referring back to FIG. 12D, as the sacrificial layers SAL are selectively removed, only the first, second, and third semiconductor patterns SP1, SP2, and SP3 stacked on each of the first and second active patterns AP1 and AP2 may remain. First, second, and third inner regions IRG1, IRG2, and IRG3 may be respectively formed through regions where the sacrificial layers SAL are removed.

In detail, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring back to FIGS. 12A to 12D, a gate insulating layer GI may be formed on the exposed first, second, and third semiconductor patterns SP1, SP2, and SP3. The gate insulating layer GI may be formed to extend around (e.g., surround) each of the first, second, and third semiconductor patterns SP1, SP2, and SP3. The gate insulating layer GI may be formed in each of the first, second, and third inner regions IRG1, IRG2, and IRG3. The gate insulating layer GI may be formed in the outer region ORG.

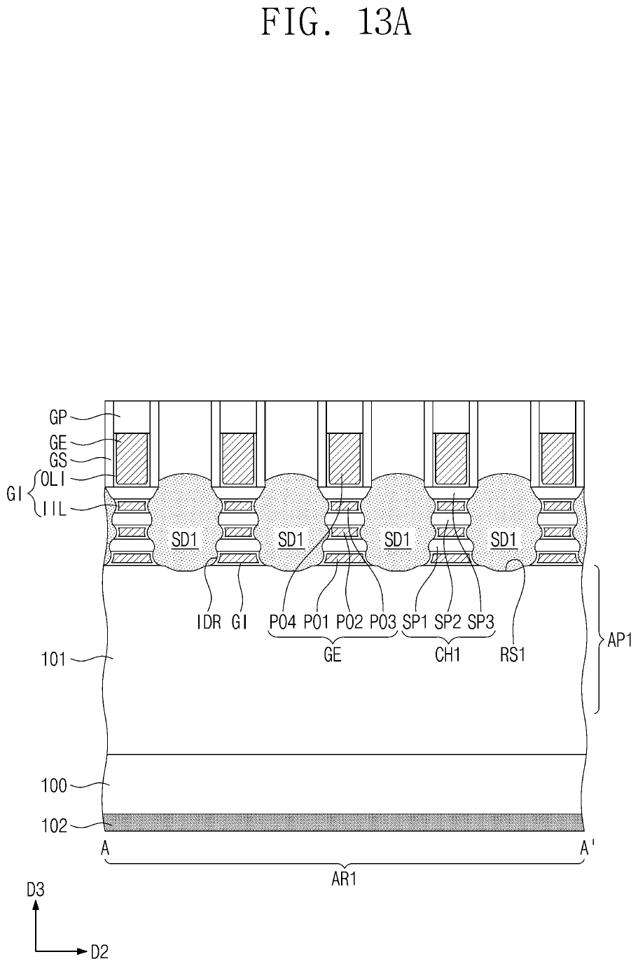

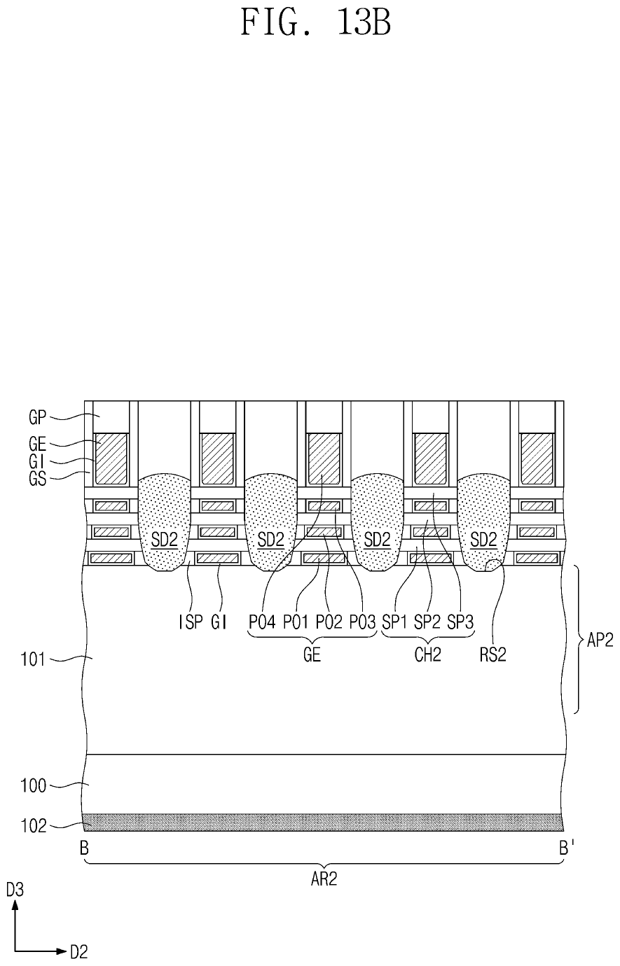

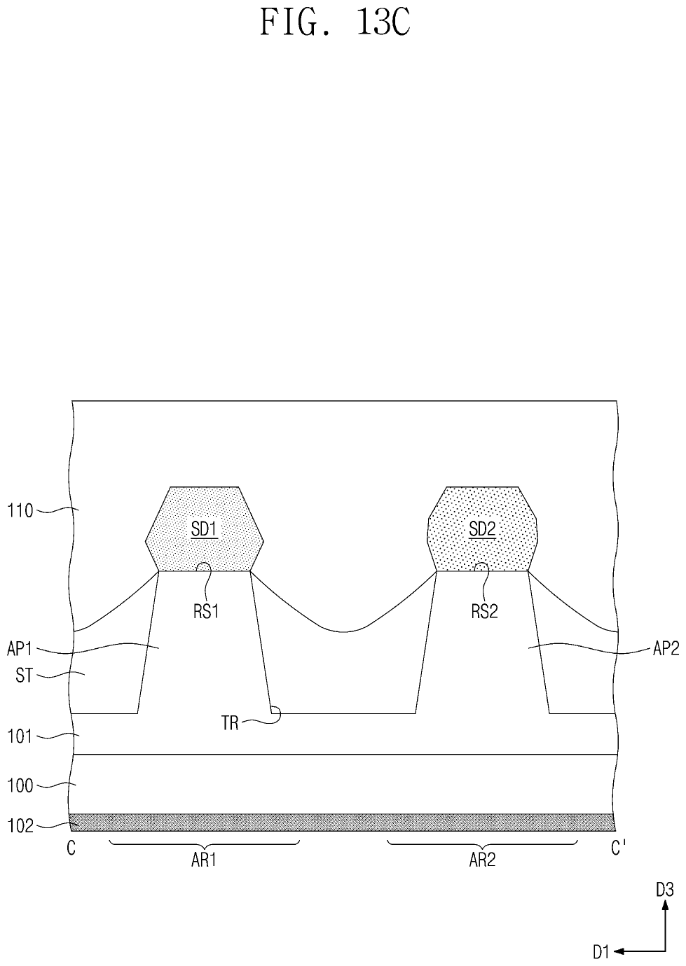

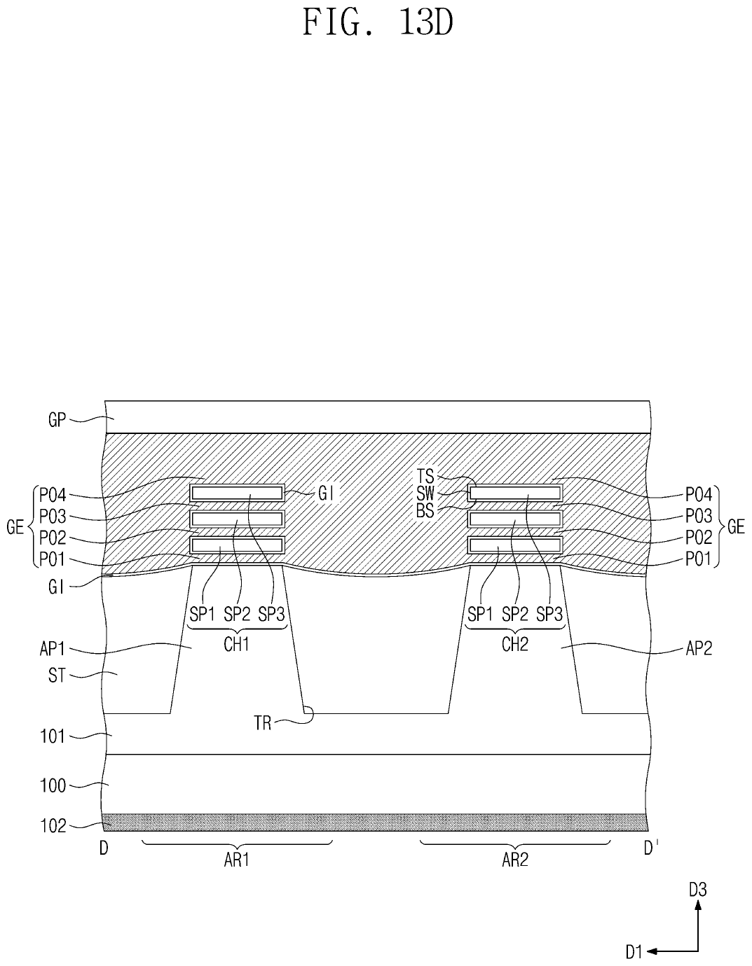

Referring to FIGS. 13A to 13D, a gate electrode GE may be formed on the gate insulating layer GI. The gate electrode GE may include first, second, and third inner electrodes PO1, PO2, and PO3 respectively formed in the first, second, and third inner regions IRG1, IRG2, and IRG3, and an outer electrode PO4 formed in an outer region ORG. As the gate electrode GE is recessed, a height thereof may be reduced. A gate capping pattern GP may be formed on the recessed gate electrode GE.

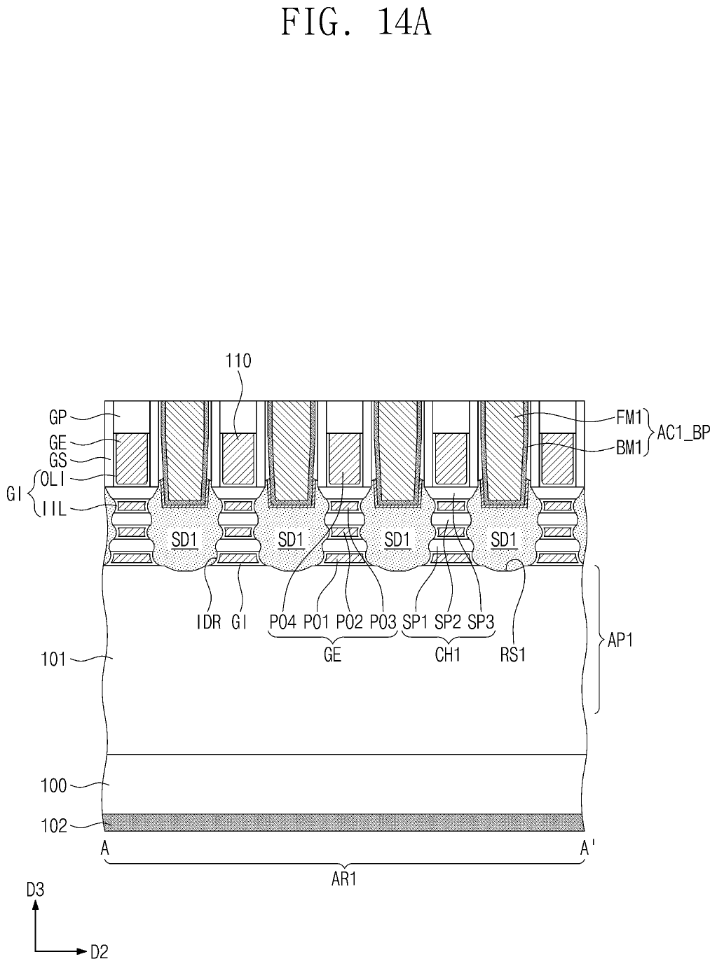

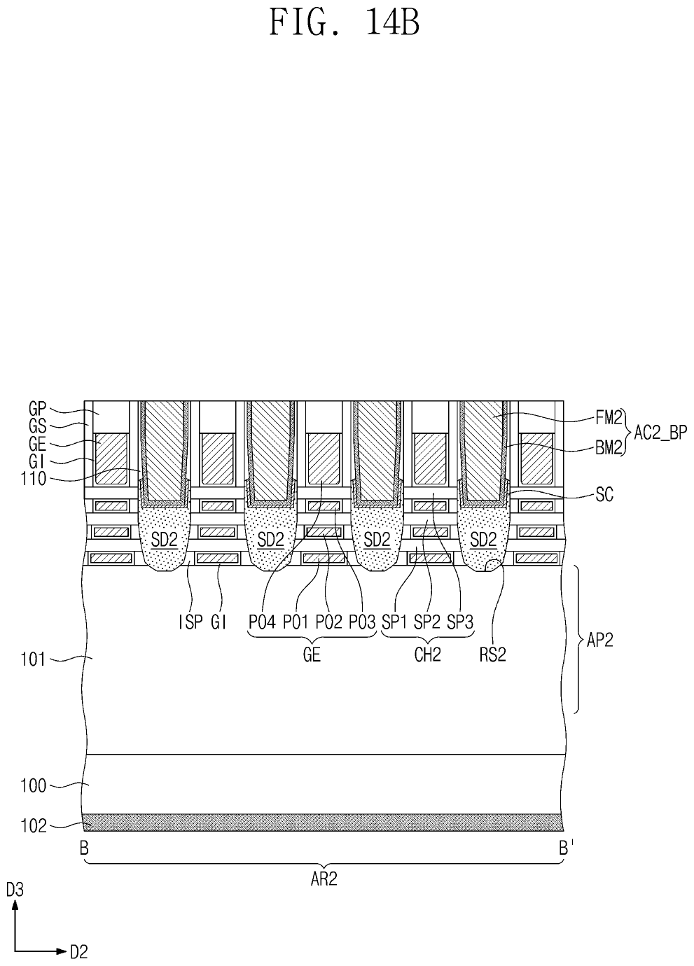

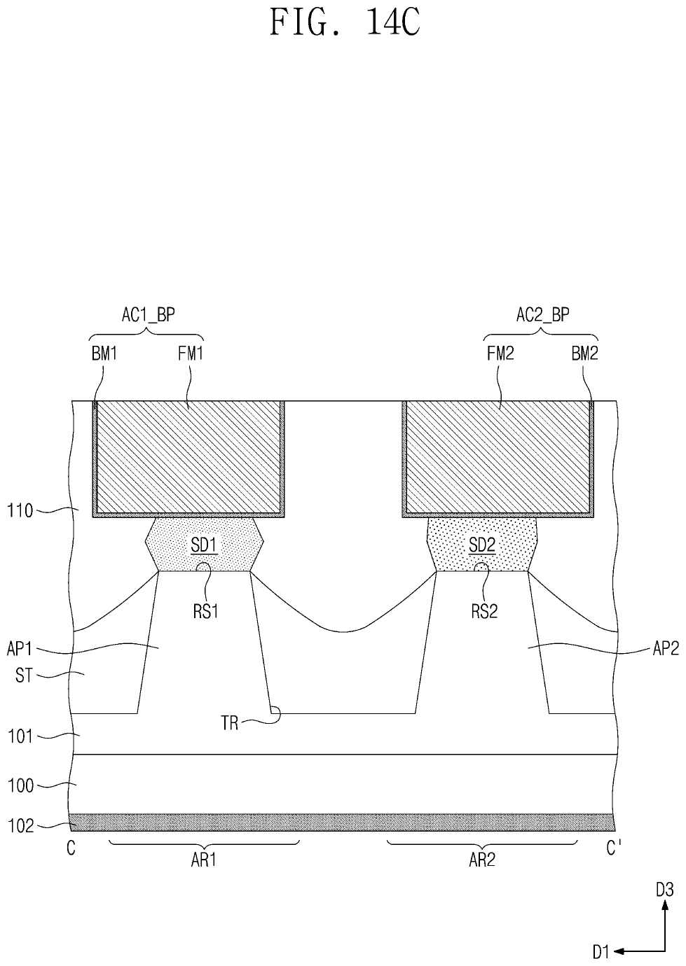

Referring to FIGS. 14A to 14C, first and second recess regions penetrating the first interlayer insulating layer 110 may be formed. The first and second recess regions may be formed by performing a dry etching process. Each of the first and second recess regions may penetrate the first interlayer insulating layer 110 and extend to corresponding upper portions of the first source/drain pattern SD1 and the second source/drain pattern SD2, respectively.

Forming a first lower active contact AC1_BP may include forming a first barrier pattern BM1 in the first recess region and forming a first conductive pattern FM1 on the first barrier pattern BM1. Forming a second lower active contact AC2_BP may include forming a second barrier pattern BM2 in the second recess region and forming a second conductive pattern FM2 on the second barrier pattern BM2.

In detail, forming the first and second conductive patterns FM1 and FM2 may include depositing a conductive material on each of the first and second barrier patterns BM1 and BM2 and planarizing the first and second barrier patterns BM1 and BM2 by performing a CMP process. The planarization may include performing a CMP process until upper surfaces of the gate capping pattern GP and the gate spacer GS are exposed.

Each of the first barrier pattern BM1 and the second barrier pattern BM2 may be conformally formed in corresponding recess regions (e.g., the first and second recess regions) and may include, for example, a metal layer or a metal nitride layer. For example, the first barrier pattern BM1 and the second barrier pattern BM2 may include TiN. The first conductive pattern FM1 and the second conductive pattern FM2, for example, may include a low-resistance metal. For example, the first conductive pattern FM1 and the second conductive pattern FM2 may include tungsten.

Referring back to FIGS. 2A to 2D, a gate contact GC electrically connected to the gate electrode GE may be formed through the second interlayer insulating layer 120 and the gate capping pattern GP. Forming the gate contact GC may include forming a barrier pattern BM and forming a conductive pattern FM on the barrier pattern BM. The barrier pattern BM may be conformally formed and may include, for example, a metal layer/metal nitride layer. The conductive pattern FM may include, for example, a low-resistance metal.

Separation structures DB may be respectively formed on a first boundary BD1 and a second boundary BD2 of a single height cell SHC. The separation structure DB may extend from the second interlayer insulating layer 120 into the active pattern AP1 or AP2 through the gate electrode GE. The separation structure DB may include an insulating material such as a silicon oxide layer or a silicon nitride layer.

A third interlayer insulating layer 130 may be formed on the first and second active contact structures AC1 (e.g., the first lower active contact AC1_BP) and AC2 (e.g., the second lower active contact AC2_BP) and the gate contact GC. A first metal layer M1 may be formed in the third interlayer insulating layer 130. A fourth interlayer insulating layer 140 may be formed on the third interlayer insulating layer 130. A second metal layer M2 may be formed in the fourth interlayer insulating layer 140.

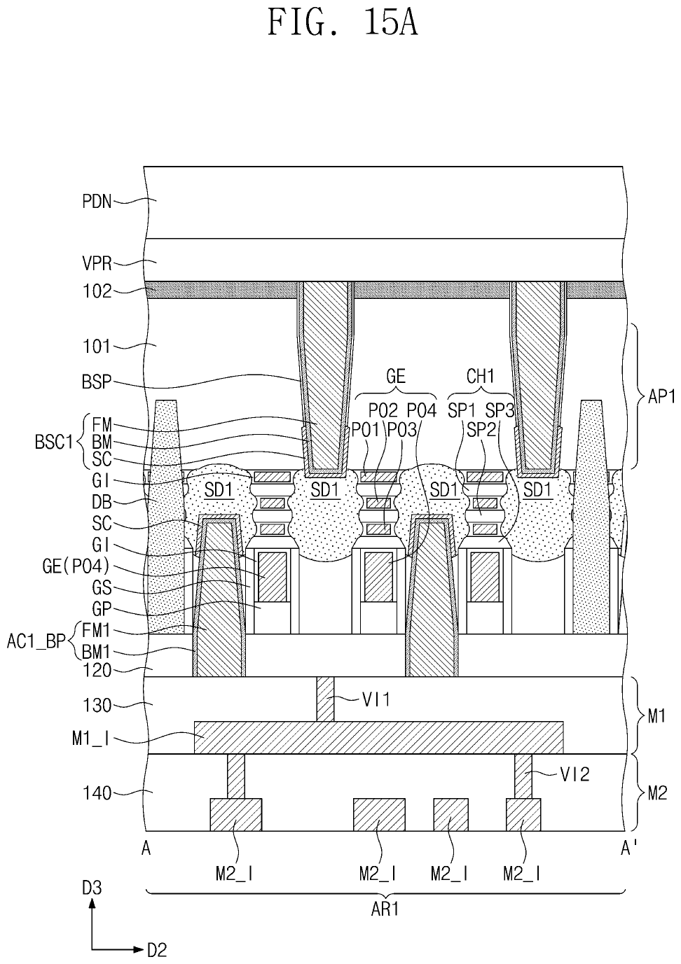

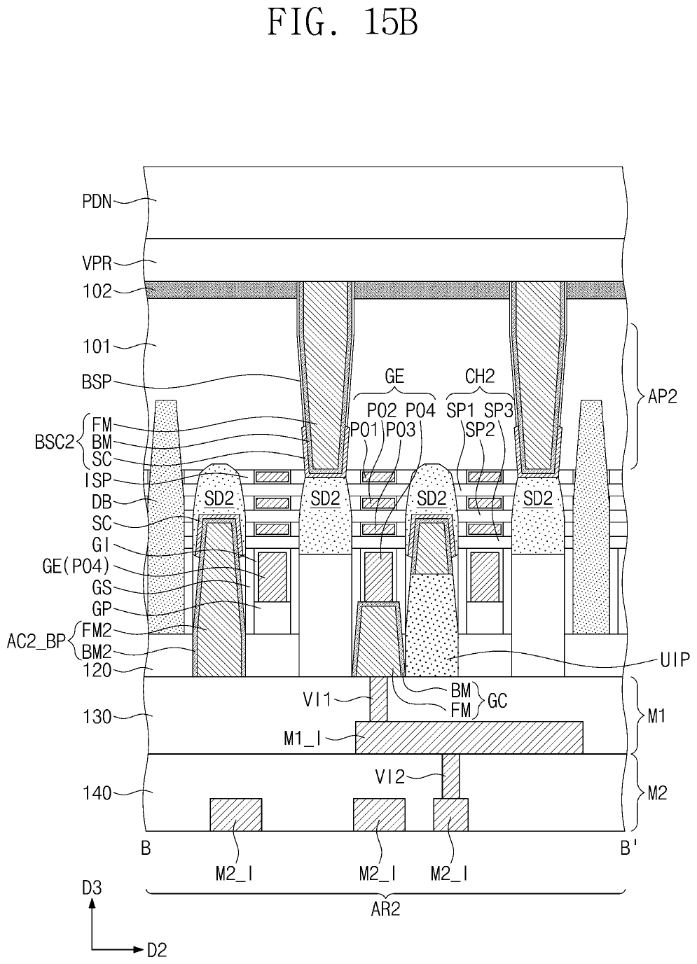

FIGS. 15A and 15B are views of a semiconductor device according to some embodiments of the present disclosure, which are cross-sectional views taken along lines A-A′ and B-B′ of FIG. 1, respectively. Descriptions of portions overlapping with those of FIGS. 2A and 2B may be omitted. A lower power wirings VPR may be provided on the epitaxial layer 101. The lower power wirings VPR may extend parallel to each other in the second direction D2. The lower power wiring VPR may include at least one selected from the group consisting of copper, molybdenum, tungsten, and ruthenium.

A power transmission network layer PDN may be provided on the lower power wiring VPR. The power transmission network layer PDN may include a plurality of lower wirings electrically connected to the lower power wirings VPR. The power transmission network layer PDN may include a wiring network for applying a drain voltage VDD or a source voltage VSS to the lower power wiring VPR.

A first back contact BSC1 extending vertically (e.g., in the third direction D3) from the lower power wirings VPR to the first source/drain pattern SD1 through the epitaxial layer 101 and the diffusion barrier layer 102 may be provided in the first active region AR1. A second back contact BSC2 extending vertically (e.g., in the third direction D3) from the lower power wiring VPR to the second source/drain pattern SD2 through the epitaxial layer 101 and the diffusion barrier layer 102 may be provided in the second active region AR2.

The first back contact BSC1 may have a conductive pillar shape that vertically and electrically connects the lower power wiring VPR and the first source/drain pattern SD1. The drain voltage VDD may be applied to the first source/drain pattern SD1 through the first back contact BSC1.

The second back contact BSC2 may have a conductive pillar shape that vertically and electrically connects the lower power wiring VPR and the second source/drain pattern SD2. The source voltage VSS may be applied to the second source/drain pattern SD2 through the second back contact BSC2.

The first and second back contacts BSC1 and BSC2 may include a conductive pattern FM, a barrier pattern BM extending around (e.g., at least partially surrounding) the conductive pattern FM, and a metal-semiconductor compound layer SC interposed between the barrier pattern BM and the first and second source/drain patterns SD1 and SD2. The conductive pattern FM and the barrier pattern BM of the first and second back contacts BSC1 and BSC2 may be substantially the same as the conductive pattern FM and the barrier pattern BM of the active contact AC (e.g., the first lower active contact AC1_BP and the second lower active contact AC2_BP). For example, the conductive pattern FM may include, for example, aluminum, copper, tungsten, molybdenum, and/or cobalt. The barrier pattern BM may include, for example, a metal layer/metal nitride layer. The metal layer may include, for example, titanium, tantalum, tungsten, nickel, cobalt, and/or platinum. The metal nitride layer may include, for example, a titanium nitride layer (TiN), a tantalum nitride layer (TaN), a tungsten nitride layer (WN), a nickel nitride layer (NiN), a cobalt nitride layer (CON), and/or a platinum nitride layer (PtN).

The barrier pattern BM may be on (e.g., cover) an upper surface and sidewalls of the conductive pattern FM. The metal-semiconductor compound layer SC may include, for example, titanium-silicide, tantalum-silicide, tungsten-silicide, nickel-silicide, and/or cobalt-silicide.

A back spacer BSP may be interposed between the first and second back contacts BSC1 and BSC2 and the epitaxial layer 101. The back spacer BSP may have a spacer shape. The back spacer BSP may cover portions of side surfaces of the first and second back contacts BSC1 and BSC2.

Meanwhile, although not shown, an etch stop layer may be disposed on the epitaxial layer 101 before performing an etching process for forming the first and second back surface contacts BSC1 and BSC2. The etch stop layer may include, for example, SiGe, and a concentration of Ge may correspond to 15% to 40%.

In the case of the conventional semiconductor device, when an etching process is performed on an epitaxial layer or a substrate to form a back contact, compressive stress applied between source/drain patterns may be removed. Therefore, when forming the back contact, an effect of improving mobility of holes may not occur as the compressive stress disappears. On the other hand, in the case of the present disclosure, even when the back contact is formed by performing the etching process on the epitaxial layer after flipping the semiconductor device, the epitaxial layer may have the {110} crystal plane, which increases the hole mobility by about 2.4 times compared to the existing {100} crystal plane. Therefore, electrical characteristics and reliability of the semiconductor device may be improved.

In the semiconductor device according to the inventive concept of the present disclosure, the substrate and the epitaxial layer on the substrate may include the {110} crystal plane, and the hole mobility may be increased in the PMOSFET region. The channel patterns may be disposed on the epitaxial layer, and each of the channel patterns may be configured such that the carriers move in the <110> direction. Each of the channel patterns may include the surface pattern disposed in the <100> direction perpendicular to the <110> direction or in the direction less than 30° of the <100> direction. When the moving direction of the carriers and the arrangement direction of the steps are perpendicular to each other, the carriers may move without being affected by the steps when moving on the surface of the channel pattern. As a result, As increasing the carrier mobility, the electrical characteristics of the device may be improved and the reliability of the semiconductor device may be increased.

While embodiments are described above, a person skilled in the art may understand that many modifications and variations are made without departing from the scope of the present disclosure defined in the following claims. Accordingly, the example embodiments of the present disclosure should be considered in all respects as illustrative and not restrictive, with the spirit and scope of the present disclosure being indicated by the appended claims.

What is claimed is:

1. A semiconductor device comprising:
a semiconductor substrate;
source/drain patterns spaced apart in a first direction on the semiconductor substrate; and
channel patterns on the semiconductor substrate,
wherein at least one of the channel patterns is between adjacent source/drain patterns among the source/drain patterns,
wherein at least one of the channel patterns includes a plurality of semiconductor patterns, and the plurality of semiconductor patterns are spaced apart from each other in a second direction that is perpendicular to an upper surface of the semiconductor substrate,
wherein the semiconductor substrate includes a {110} crystal plane,
wherein at least one of the channel patterns includes a surface pattern,
wherein the surface pattern includes first surfaces and second surfaces,
wherein the first surfaces include protruding edges,
wherein the second surfaces are respectively connected to the first surfaces through protruding edges, and
wherein the protruding edges are arranged in a third direction.

2. The semiconductor device of claim 1, wherein the third direction is in a same direction as a fourth direction perpendicular to the first direction or is 30° or less with respect to the fourth direction.

3. The semiconductor device of claim 2, wherein the first direction is in a <110> direction, and
wherein the fourth direction is in a <100> direction.

4. The semiconductor device of claim 1, wherein a length of at least one of the second surfaces is 1.9 Å to 38 Å.

5. The semiconductor device of claim 1, wherein a carrier moving direction in the channel patterns is the first direction.

6. The semiconductor device of claim 1, further comprising an epitaxial layer on the semiconductor substrate, and
wherein the epitaxial layer includes a {110} crystal plane.

7. The semiconductor device of claim 6, wherein a distance between adjacent protruding edges among the protruding edges is 20 nm to 300 nm.

8. The semiconductor device of claim 1, further comprising a diffusion barrier layer on a lower surface of the semiconductor substrate.

9. The semiconductor device of claim 1, wherein the semiconductor substrate includes impurities, and
wherein the impurities include nitrogen, boron, gallium, indium, phosphorus, arsenic, and/or antimony.

10. The semiconductor device of claim 9, wherein a concentration of the impurities is 1.00E⁺¹⁸/cm³ to 1.00E⁺²⁰/cm³.

11. A semiconductor device comprising:
a semiconductor substrate;
an epitaxial layer on the semiconductor substrate;
source/drain patterns spaced apart in a first direction on the epitaxial layer;
channel patterns on the epitaxial layer, wherein at least one of the channel patterns is between adjacent source/drain patterns among the source/drain patterns;
a gate electrode on at least one of the channel patterns;
a gate insulating layer between the gate electrode and the channel patterns;
an interlayer insulating layer on the gate insulating layer; and
active contacts electrically connected to the source/drain patterns through the interlayer insulating layer,
wherein the semiconductor substrate includes a first surface that comprises a {110} crystal plane,
wherein the epitaxial layer includes a second surface that comprises a {110} crystal plane, and
wherein an upper surface of the semiconductor substrate is inclined from the first surface by a crystal off angle.

12. The semiconductor device of claim 11, wherein the crystal off angle is 5° or less.

13. The semiconductor device of claim 11, wherein the upper surface of the semiconductor substrate is tilted by a direction off angle in a second direction that is a <100> direction with respect to the first surface and is inclined by the crystal off angle.

14. The semiconductor device of claim 13, wherein the direction off angle is 30° or less.

15. The semiconductor device of claim 13, wherein the second direction is perpendicular to a carrier moving direction in the channel patterns.

16. The semiconductor device of claim 11, wherein the epitaxial layer includes impurities, and
wherein the impurities include boron, gallium, indium, phosphorus, arsenic, and/or antimony, and a concentration of the impurities included in the epitaxial layer is 1.00E⁺¹⁴/cm³ to 5.00E⁺¹⁴/cm³.

17. A semiconductor device comprising:
an epitaxial layer;
source/drain patterns spaced apart in a first direction on the epitaxial layer; and
channel patterns on the epitaxial layer, wherein at least one of the channel patterns is between adjacent source/drain patterns among the source/drain patterns;
a gate electrode on at least one of the channel patterns;
a gate insulating layer between the gate electrode and the channel patterns;
an interlayer insulating layer on the gate insulating layer; and
active contacts electrically connected to the source/drain patterns through the interlayer insulating layer;
a lower power wiring on a lower surface of the epitaxial layer; and
a back contact electrically connecting the lower power wiring and the source/drain patterns through the epitaxial layer,
wherein the epitaxial layer comprises a {110} crystal plane,
wherein the epitaxial layer includes a first surface pattern that includes first edges protruding in a second direction perpendicular to the first direction,
wherein the first surface pattern includes first surfaces and second surfaces that are respectively connected to the first surfaces through the first edges,
wherein at least one of the channel patterns includes a second surface pattern that includes second edges protruding in the second direction, and
wherein the second surface pattern includes third surfaces and fourth surfaces that are respectively connected to the third surfaces through the second edges.

18. The semiconductor device of claim 17, further comprising a power transmission network layer on the lower power wiring.

19. The semiconductor device of claim 17, further comprising a diffusion barrier between the lower surface of the epitaxial layer and the lower power wiring.

20. The semiconductor device of claim 17, wherein two or more of the first surfaces and the third surfaces are disposed in the second direction.
